(19) United States
(12) Patent Application Publication
(10) Pub. No.: US 2025/0162093 A1
(43) Pub. Date: May 22, 2025

(54) WIRE BONDING SYSTEMS, WIRE BONDING TOOL REPLACEMENT SYSTEMS, AND RELATED METHODS

(71) Applicant: KULICKE AND SOFFA INDUSTRIES, INC., Fort Washington, PA (US)

(72) Inventors: Kumar Manoj Venna, Singapore (SG); Wei Jing, Singapore (SG); Jianxu Ma, Singapore (SG); Kay Soon Goh, Singapore (SG); Kyaw Zan Khine, Singapore (SG); Wei Qin, Ambler, PA (US)

(73) Assignee: KULICKE AND SOFFA INDUSTRIES, INC., Fort Washington, PA (US)

(21) Appl. No.: 18/947,365

(22) Filed: Nov. 14, 2024

Related U.S. Application Data
(60) Provisional application No. 63/601,286, filed on Nov. 21, 2023.

(51) Int. Cl. B23Q 3/155; H01L 23/00

(52) U.S. Cl. CPC B23Q 3/15503; H01L 24/78; H01L 2224/78821; H01L 2224/789

(57) ABSTRACT

A wire bonding system is provided. The wire bonding system includes (i) a bond head assembly configured to carry a wire bonding tool; and (il) a wire bonding tool replacement system for replacement of the wire bonding tool with another wire bonding tool.

### CROSS-REFERENCE TO RELATED APPLICATION

This application claims the benefit of U.S. Provisional Application No. 63/601,286 filed on Nov. 21, 2023, the content of which is incorporated herein by reference.

### FIELD

The invention relates to wire bonding systems, and in particular, to wire bonding systems including wire replacement systems and/or wire bonding tool replacement systems.

### BACKGROUND

In the processing and packaging of semiconductor devices, wire bonding continues to be the primary method of providing electrical interconnection between two locations within a package (e.g., between a die pad of a semiconductor die and a lead of a leadframe). More specifically, using a wire bonder (also known as a wire bonding system) wire loops are formed between respective locations to be electrically interconnected. The primary methods of forming wire loops are ball bonding and wedge bonding. In forming the bonds between (a) the ends of the wire loop and (b) the bond site (e.g., a die pad, a lead, etc.) varying types of bonding energy may be used, including, for example, ultrasonic energy, thermosonic energy, thermocompressive energy, amongst others. Wire bonding systems (e.g., stud bumping machines) are also used to form conductive bumps from portions of wire.

Replacement of a portion of wire on a wire bonding system, and/or replacements of a wire bonding tool on a wire bonding system, often results in significant delays or machine downtime. Thus, it would be desirable to provide improved wire bonding systems for addressing such concerns.

### SUMMARY

According to an exemplary embodiment of the invention, a wire bonding system is provided. The wire bonding system includes a bond head assembly configured to carry a wire bonding tool. The wire bonding system also includes a wire bonding tool replacement system for replacement of the wire bonding tool with another wire bonding tool.

According to another exemplary embodiment of the invention, a wire bonding tool replacement system for replacing a wire bonding tool on a wire bonding system is provided. The wire bonding tool replacement system includes a clamping mechanism for clamping the wire bonding tool to remove the wire bonding tool from a bond head assembly of a wire bonding system.

According to other embodiments of the invention, the wire bonding system and/or the wire bonding tool replacement system recited in the two immediately preceding paragraphs may have any one or more of the following features: the wire bonding tool replacement system includes a clamping mechanism for clamping the wire bonding tool to remove the wire bonding tool from the bond head assembly; the clamping mechanism includes (i) a threading portion for threading wire, and (ii) a tool clamping portion for clamping the wire bonding tool; the clamping mechanism includes a spring for providing a clamping force in connection with a clamping operation; the clamping mechanism is configured for retrieving the another wire bonding tool from a wire bonding tool source, and for carrying the another wire bonding tool to the bond head assembly; the wire bonding tool source is configured to provide a plurality of wire bonding tools; the wire bonding tool replacement system includes a receptacle for receiving used wire bonding tools; a wire bonding tool source defining the receptacle; the clamping mechanism is carried by a moveable arm assembly; the moveable arm assembly is further configured for removing a wire from the wire bonding tool, and for replacing wire in connection with replacement of the wire bonding tool; the wire bonding tool replacement system is configured to be removed from the wire bonding system; the wire bonding tool replacement system is further configured for installation in connection with another wire bonding system; the wire bonding tool replacement system is configured to automatically replace the wire bonding tool upon the occurrence of a predetermined event; the clamping mechanism includes an image registration feature, the image registration feature providing a reference for determining a position of the clamping mechanism; a vision system configured to determine the position of the clamping mechanism by collecting an image of the image registration feature; an optical path between the vision system and the image registration feature includes a reflective optical element; and an optical path between the vision system and the image registration feature includes a refractive optical element.

According to another exemplary embodiment of the invention, a method of replacing a wire bonding tool using a wire bonding tool replacement system on a wire bonding machine is provided. The method includes the steps of: removing a wire bonding tool from a bond head assembly using the wire bonding tool replacement system; and providing another wire bonding tool to the bond head assembly using the wire bonding tool replacement system.

According to other embodiments of the invention, the method recited in the immediately preceding paragraph may have any one or more of the following features: the wire bonding tool replacement system includes a clamping mechanism for clamping the wire bonding tool to remove the wire bonding tool from the bond head assembly; the clamping mechanism includes a spring for providing a clamping force in connection with a clamping operation; the clamping mechanism is configured for retrieving the another wire bonding tool from a wire bonding tool source, and for carrying the another wire bonding tool to the bond head assembly; the wire bonding tool source is configured to provide a plurality of wire bonding tools; the wire bonding tool replacement system includes a receptacle for receiving used wire bonding tools; the wire bonding tool source defining the receptacle; the clamping mechanism is carried by a moveable arm assembly; the moveable arm assembly is further configured for removing wire from the wire bonding tool, and for replacing wire in connection with replacement of the wire bonding tool; the wire bonding tool replacement system is configured to be removed from the wire bonding system; the wire bonding tool replacement system is further configured for installation in connection with another wire bonding system; the wire bonding tool replacement system is configured to automatically replace the wire bonding tool upon the occurrence of a predetermined event; further including the step of removing a portion of wire from the wire bonding tool; and/or further including the step of providing a portion of wire through the another wire bonding tool.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1F are various perspective views of portions of a wire bonding system in accordance with an exemplary embodiment of the invention;

FIGS. 2A-2B are perspective views of a wire bonding tool source in accordance with an exemplary embodiment of the invention;

FIGS. 2C-2D are perspective views of another wire bonding tool source in accordance with an exemplary embodiment of the invention;

FIGS. 3A-3H are various block diagram side views of the wire bonding system of FIGS. 1A-1F;

FIGS. 4A-4D are various perspective views of elements of another wire bonding system in accordance with an exemplary embodiment of the invention;

FIGS. 5A-5H are various block diagram side views of elements of the wire bonding system of FIGS. 3A-3D;

FIGS. 6A-6E are various perspective views illustrating a wire bonding system in accordance with another exemplary embodiment of the invention;

FIGS. 7A-7F are various block diagram side views of elements of the wire bonding system of FIGS. 6A-6E;

FIGS. 8A and 8B are perspective views illustrating yet another wire bonding system in accordance with an exemplary embodiment of the invention;

FIGS. 9A and 9B are perspective views illustrating elements of a wire bonding tool replacement system in accordance with an exemplary embodiment of the invention; and

FIGS. 10 and 11 are flow diagrams illustrating various exemplary embodiments of the invention.

### DETAILED DESCRIPTION

Various wire bonding systems (and components thereof) and related methods are provided herein. In certain embodiments, a wire bonding system includes a wire bonding tool replacement system. In certain embodiments, the wire bonding tool replacement system can be configured to automatically replace a wire bonding tool (e.g., a capillary). The wire bonding tool replacement system can be configured to: accurately position a clamping mechanism (e.g., a “gripper”) to clamp the wire bonding tool on a bonding system (e.g., a bonding machine, a “bonder”, etc.); loosen a screw (e.g., a “cap screw” or other tightening mechanism) with a robotic wrench; and/or remove a used wire bonding tool from a transducer (e.g., an ultrasonic transducer) of a wire bonding system. In certain embodiments, the wire bonding tool replacement system can be configured to: pick up a new wire bonding tool from a wire bonding tool source (e.g., a capillary supply); insert the new wire bonding tool into a wire bonding tool hole of a transducer; and/or tighten (e.g., automatically tighten) the screw prior to subsequent wire bonding operations. In certain embodiments, the wire bonding tool replacement system can be configured to provide real-time communication with a bonding system (e.g., a computer of a bonding system) in connection with: positioning a clamping mechanism with a target wire bonding tool; positioning a wire bonding tool; and/or positioning a wrench (e.g., in connection with a servo and/or robotic wrench arm assembly). In certain embodiments, the wire bonding tool replacement system can be configured to provide feedback control in connection with robotic positioning. In certain embodiments, open/short circuit detection can be used in connection with wire bonding tool replacement (e.g., wire bonding tool removal, wire bonding tool pick-up, wire bonding tool insertion, screw tightening/loosening, etc.).

Certain embodiments of the invention provide certain advantages, such as automatically replacing wire bonding tools, thereby reducing labor hours (e.g., manual labor hours).

Certain embodiments of the invention provide a wire bonding system including a wire replacement system configured to (i) remove a wire portion engaged with the wire bonding tool and (ii) to replace the wire portion (e.g., replace with the same wire portion, replace with another wire portion). Certain embodiments provide automatic wire threading with a robotic mechanism (e.g., during wire bonding tool changing operations in wire bonding systems). Certain embodiments include: performing a partial cut (e.g., a “half-cut incision”) in a wire (e.g., at a location between wire clamp and transducer) using a cutter mechanism (e.g., a blade, a cutting portion of a clamping mechanism, etc.); moving a clamping mechanism (e.g., a gripper) beneath a wire bonding tool; pulling down the wire to position the partial cut/incision at/near the middle of an inner hole of the wire bonding tool; closing a wire clamp of a bond head assembly and the clamping mechanism; pulling down on the wire with the clamping mechanism such that the wire breaks at the partial cut/incision; completing the wire threading process after removing the wire bonding tool; and/or inserting another (e.g., new) wire bonding tool. Other embodiments include: removing a wire portion engaged with the wire bonding tool, and replacing the wire portion (e.g., after replacement of the wire bonding tool) with the same wire portion without cutting and/or breaking the wire portion.

Certain embodiments of the invention provide certain advantages, such as automatically completing wire threading (e.g., in connection with wire bonding tool replacement), thereby reducing labor hours (e.g., manual labor hours). Other advantages include breaking the wire consistently to secure a wire tail position just beneath a transducer surface inside a hole of the wire bonding tool. Certain methods do not require an additional mechanism to fix the wire positioning against the hole of the wire bonding tool, but may provide high success rates nevertheless (e.g., due in part from a highly reliable alignment calibration from a wire bonding system set up).

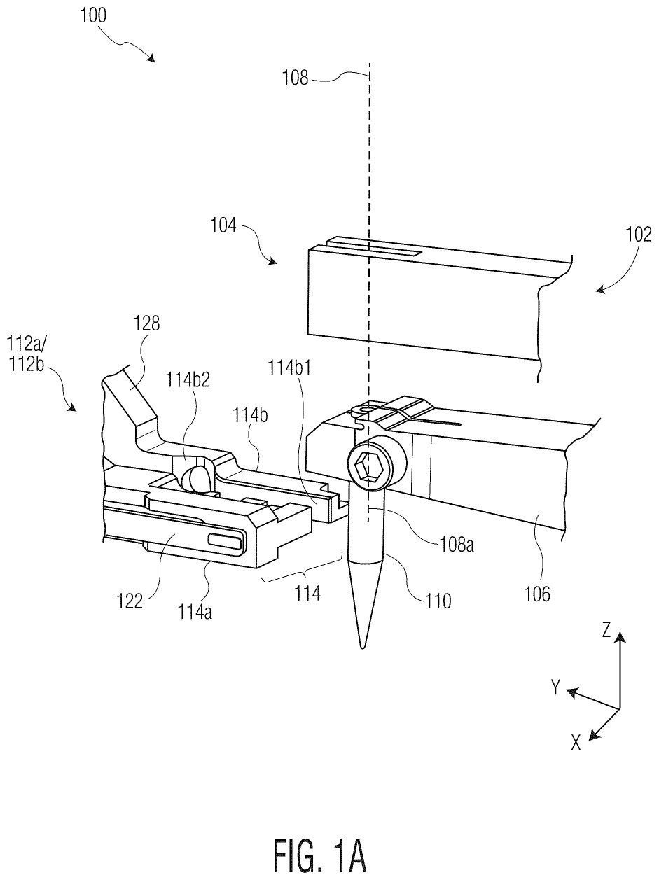

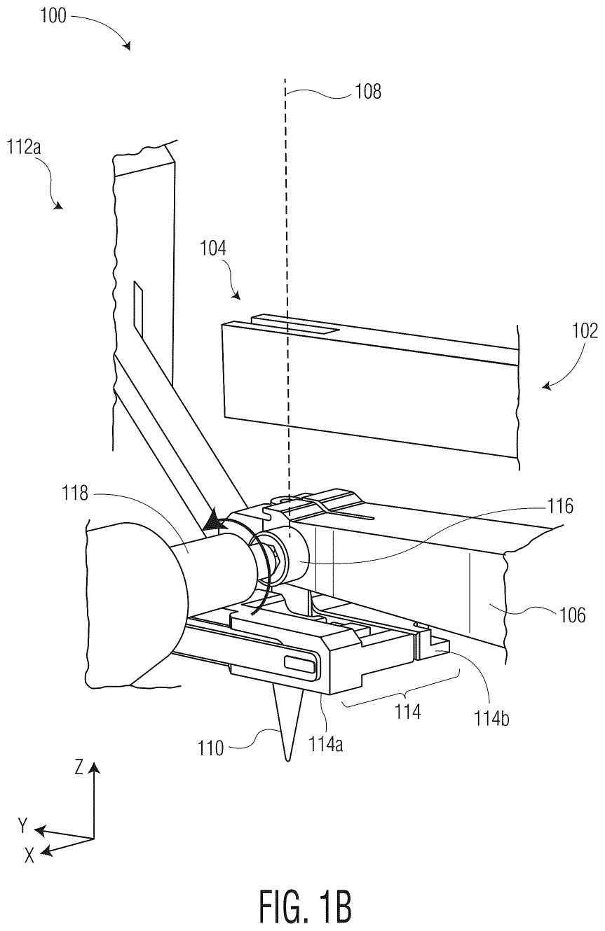

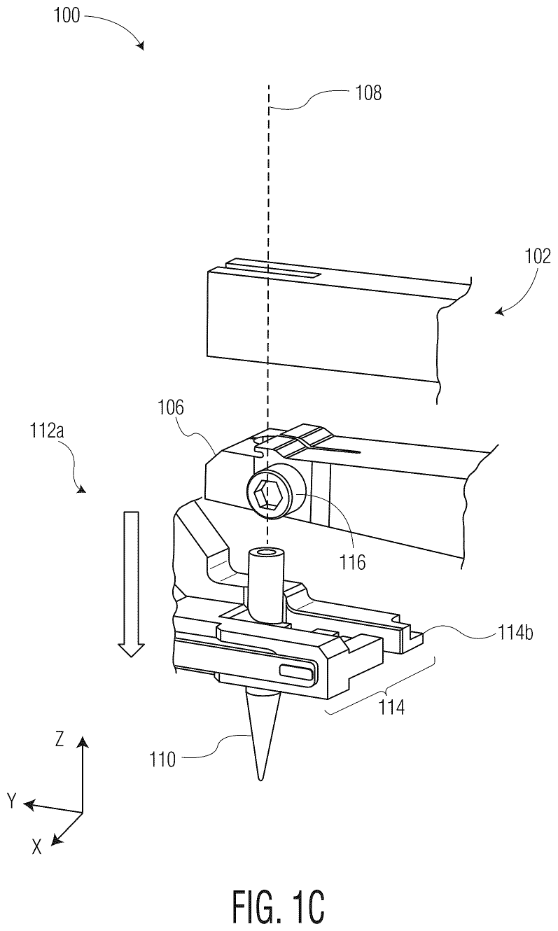

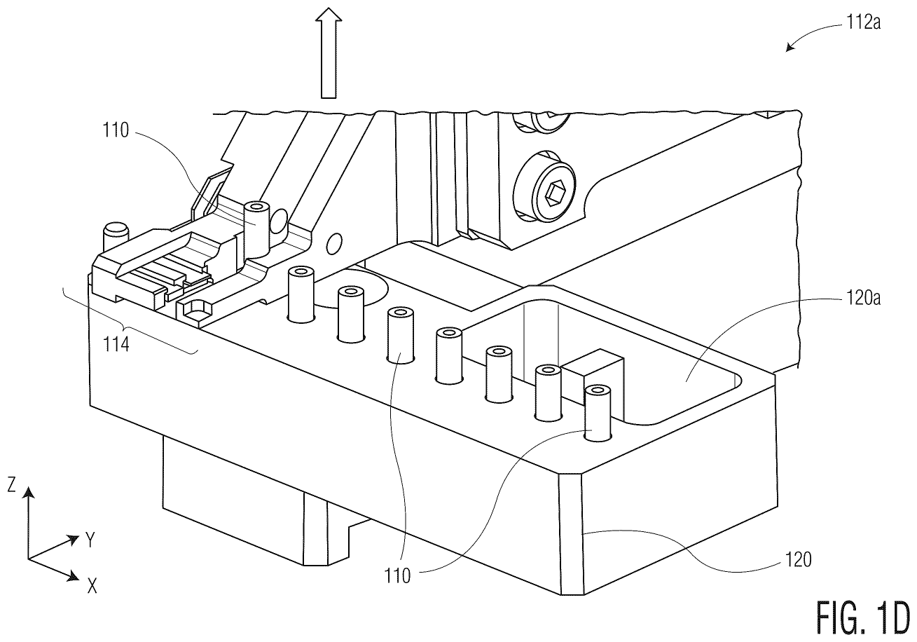

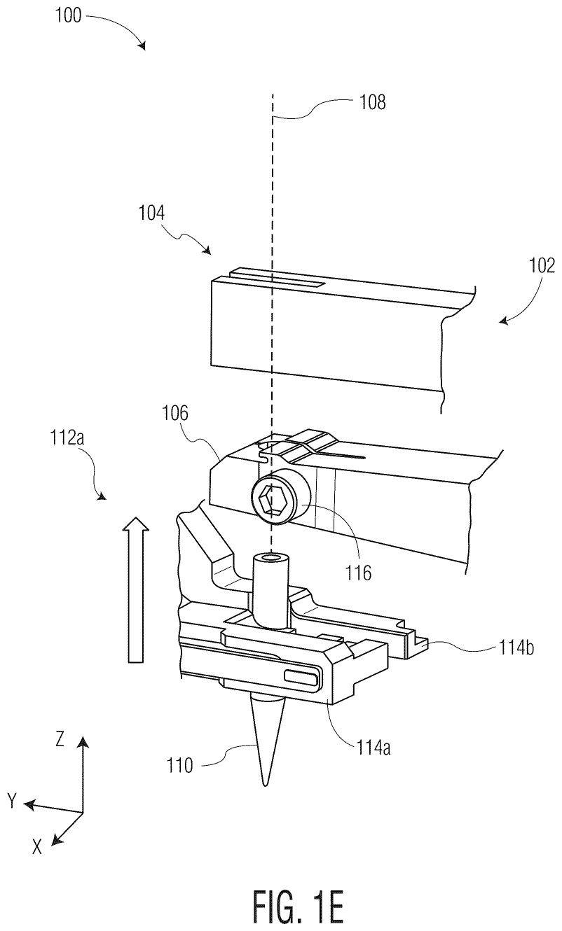

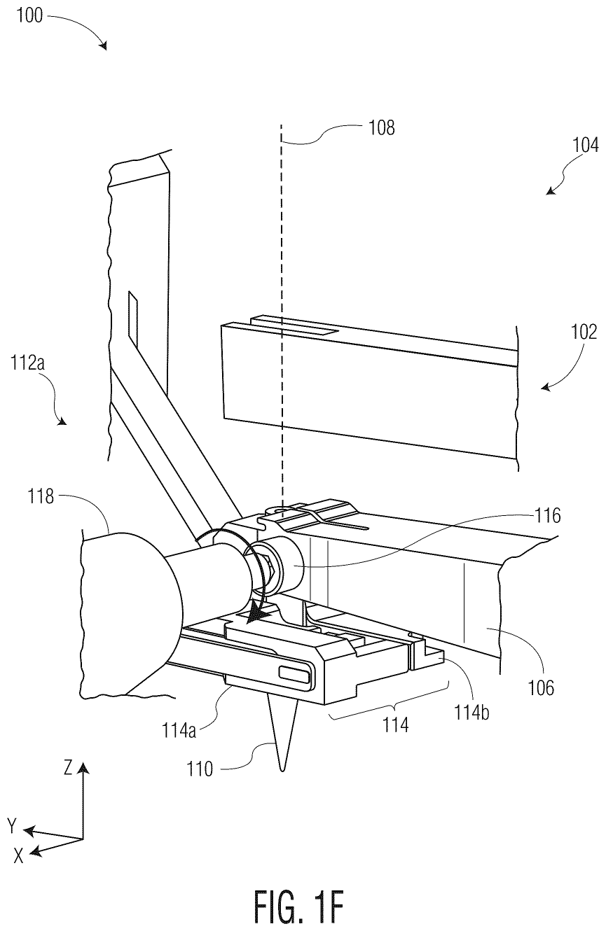

Referring now to the drawings, a wire bonding system 100 is illustrated in FIG. 1A. Wire bonding system 100 includes a bond head assembly 102 (illustrated in part) configured to carry a wire bonding tool 110. Bond head assembly 102 is illustrated including a wire clamp 104 and a transducer 106. Wire clamp 104 is configured to switch between (i) allowing a wire supply 108 to pass freely, and (ii) gripping wire supply 108 to prevent relative motion between wire supply 108 and bond head assembly 102. The invention is not limited to any particular operation of wire clamp 104 (e.g., wire clamp 104 may move one portion relative to another to grip wire supply 108, wire clamp 104 may move multiple portions relative to one another to grip wire supply 108, etc.). Wire supply 108 is illustrated disposed through both wire clamp 104 (e.g., in a closed configuration) and transducer 106. Wire supply 108 may be continuous with a wire source (e.g., a wire spool of the wire bonding system). A wire portion 108a of wire supply 108 is illustrated disposed through wire bonding tool 110.

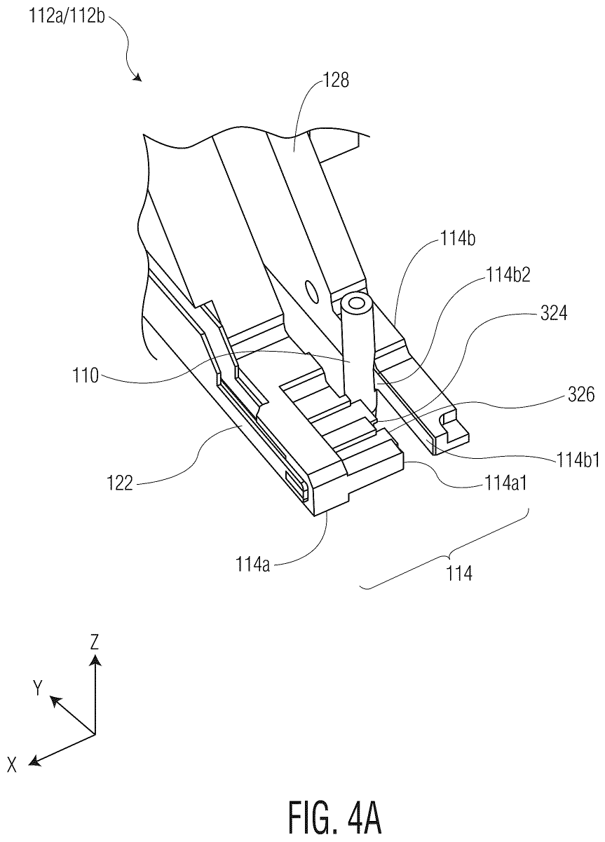

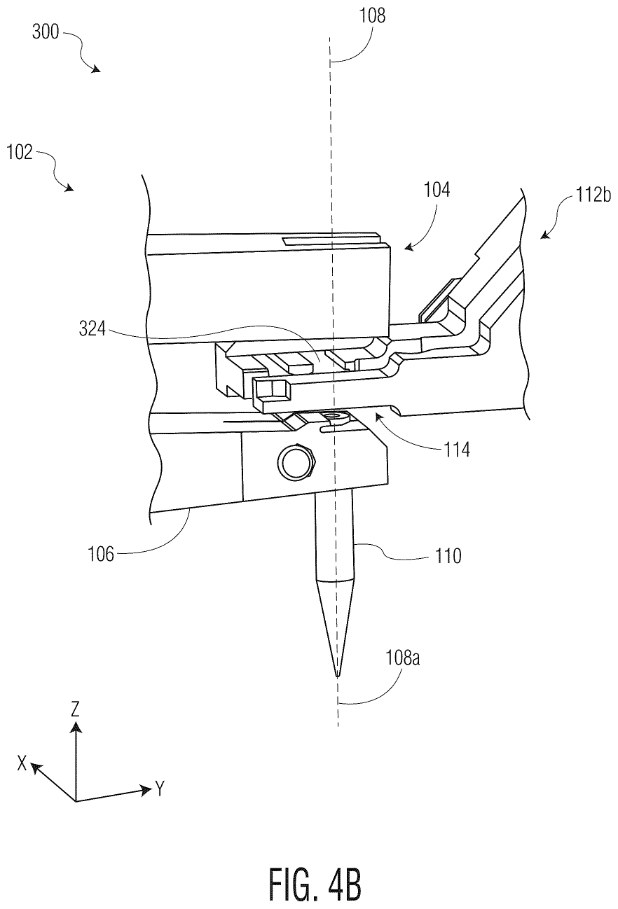

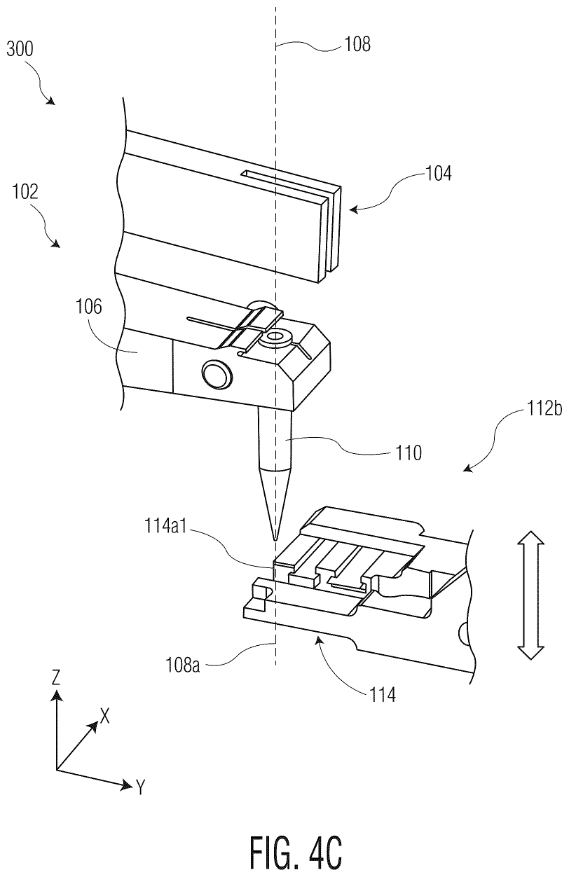

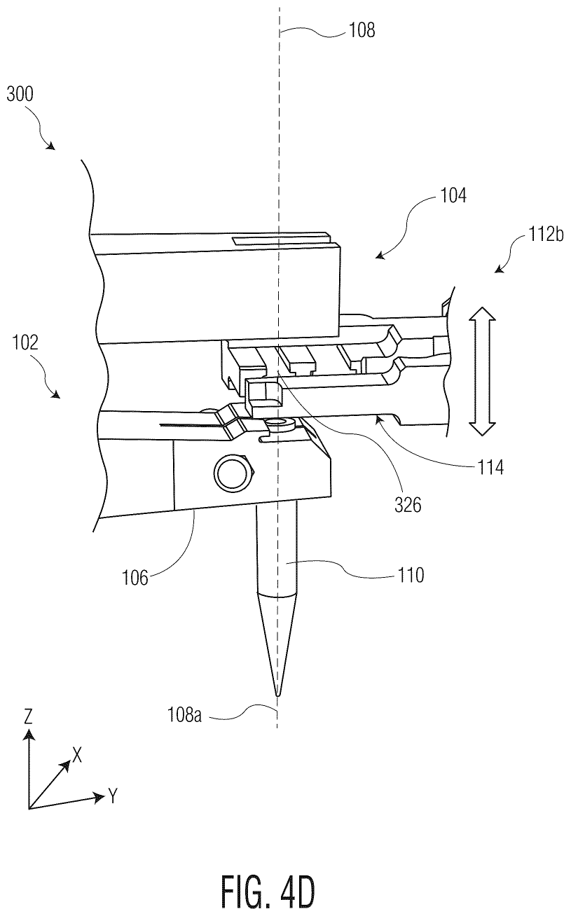

Wire bonding system 100 also includes a wire bonding tool replacement system 112a (illustrated in part). It should be understood that wire bonding tool replacement system 112a shares many of the same elements and aspects as a wire replacement system 112b and/or a wire replacement system 112b′ described elsewhere herein (e.g., FIGS. 4A-4D, FIGS. 5A-5H, FIGS. 6A-6E, FIGS. 7A-7F, etc.) in connection with wire bonding systems 300 and 600. For example, both wire bonding tool replacement system 112a and wire replacement system 112b include a clamping mechanism 114.

Wire bonding tool replacement system 112a is configured to replace wire bonding tool 110 with another wire bonding tool (e.g., another wire bonding tool 110, or a different type of wire bonding tool). Wire bonding tool replacement system 112a is illustrated including clamping mechanism 114 for clamping and/or removing wire bonding tool 110 from bond head assembly 102. Clamping mechanism 114 is illustrated carried by a moveable arm assembly 128 (illustrated in part).

Clamping mechanism 114 may be configured for clamping wire bonding tool 110 (e.g., to remove wire bonding tool 110 from bond head assembly 102). In certain embodiments, clamping mechanism 114 may be configured to include a clamping portion (e.g., a first clamp portion 114a and/or a second clamp portion 114b). In certain embodiments, clamping mechanism 114 includes (i) a gripping portion for gripping wire supply 108, (ii) a cutting portion for partially cutting wire supply 108, (iii) a threading portion for threading wire supply 108, and/or (iv) a tool clamping portion for clamping wire bonding tool 110.

Clamping mechanism 114 is illustrated including first clamp portion 114a (e.g., a moving clamp portion) and adjacent second clamp portion 114b (e.g., a fixed clamp portion). Second clamp portion 114b is illustrated including gripping portion 114b1 (e.g., for gripping and/or clamping wire supply 108 and/or wire bonding tool 110) and a tool clamping portion 114b2 (e.g., for clamping wire bonding tool 110). It should be understood that in certain embodiments, each clamp portion 114a/114b may include one or more gripper portions and tool clamping portions. First clamp portion 114a may be configured to move with respect to second clamp portion 114b in at least one direction (e.g., laterally along the x-axis).

Wire bonding tool replacement system 112a is configured to provide a clamping force sufficient to support, hold, remove, and/or replace wire bonding tool 110 in connection with a clamping operation and/or a wire bonding tool replacement operation. In certain embodiments, clamping mechanism 114 may include a spring 122 (e.g., a leaf spring) for providing a clamping force in connection with a clamping operation. Spring 122 may be configured to actuate at least part of first clamp portion 114a (e.g., a moving clamp portion, a gripping portion, a cutting portion, a threading portion, a tool clamping portion) with respect to second clamp portion 114b (e.g., a fixed clamp portion).

Referring now to FIG. 1B, wire bonding tool replacement system 112a and clamping mechanism 114 are illustrated having been moved (i.e., along the y-axis) beneath transducer 106 and around wire bonding tool 110. A wrench 118 (e.g., a cap screw wrench) is illustrated rotating about the x-axis to loosen a screw 116 (e.g., a cap screw), thereby loosening transducer 106 to release wire bonding tool 110. Prior to (or simultaneously with) tightening transducer 106, clamping mechanism 114 may clamp wire bonding tool 110 (e.g., moving first clamp portion 114a with respect to second clamp portion 114b) with a desired clamping force. In certain embodiments, wrench 118 can be included in wire bonding tool replacement system 112a (e.g., controlled by a common computing system in connection with clamping mechanism 114).

Referring now to FIG. 1C, wire bonding tool replacement system 112a and clamping mechanism 114 are illustrated moving wire bonding tool 110 away from (i.e., along the z-axis) bond head assembly 102 and transducer 106. After removing wire bonding tool 110 (e.g., a “used” or damaged wire bonding tool), wire bonding tool replacement system 112a can discard wire bonding tool 110.

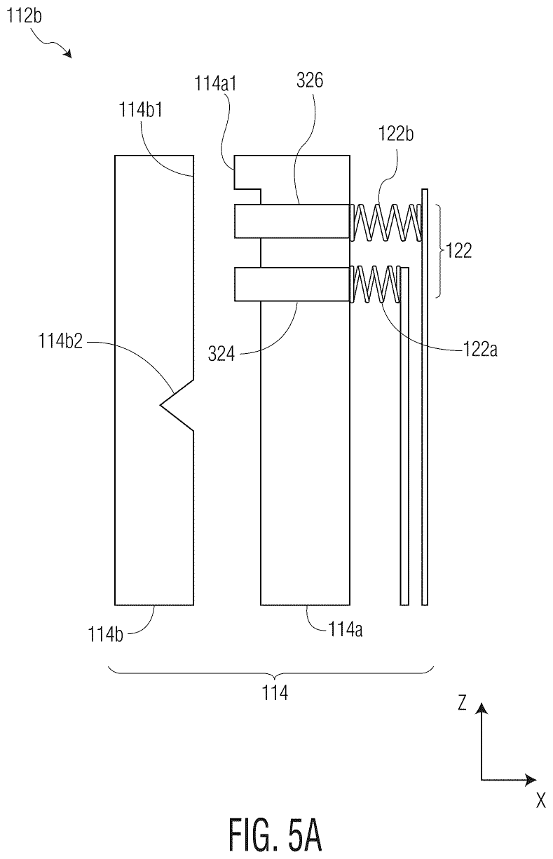

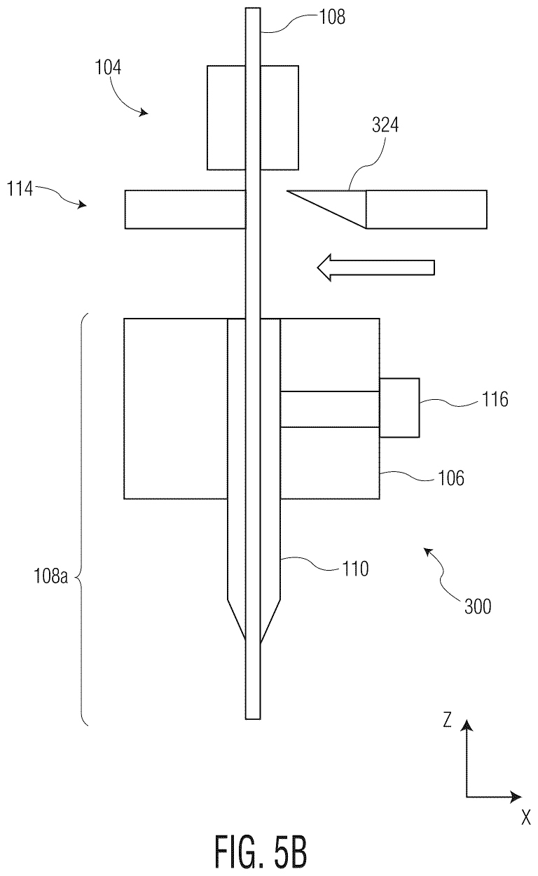

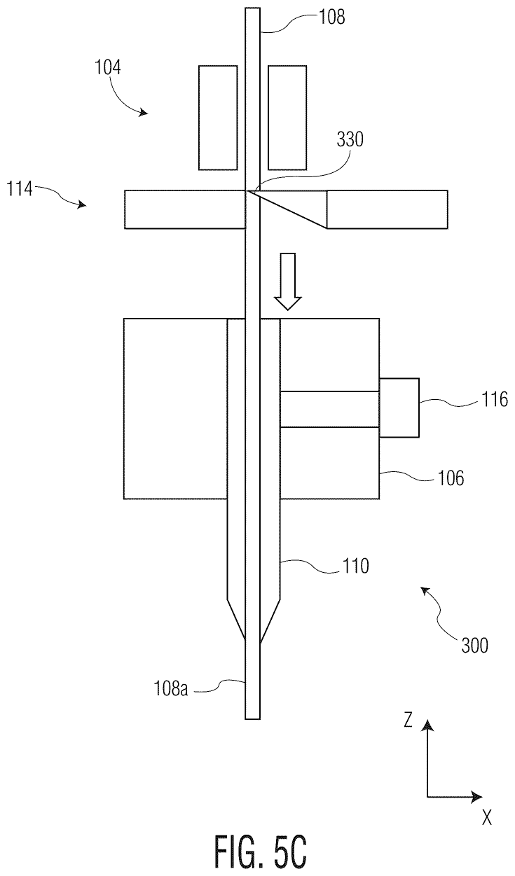

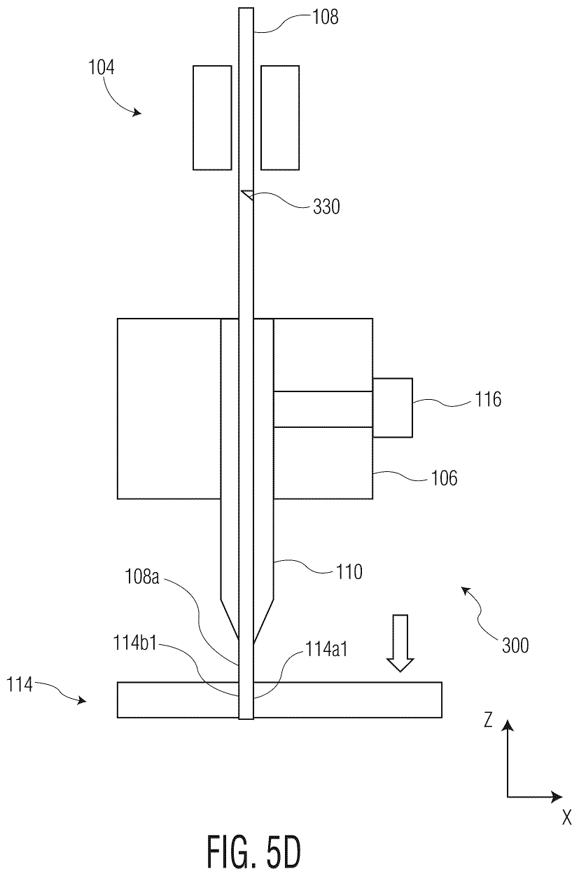

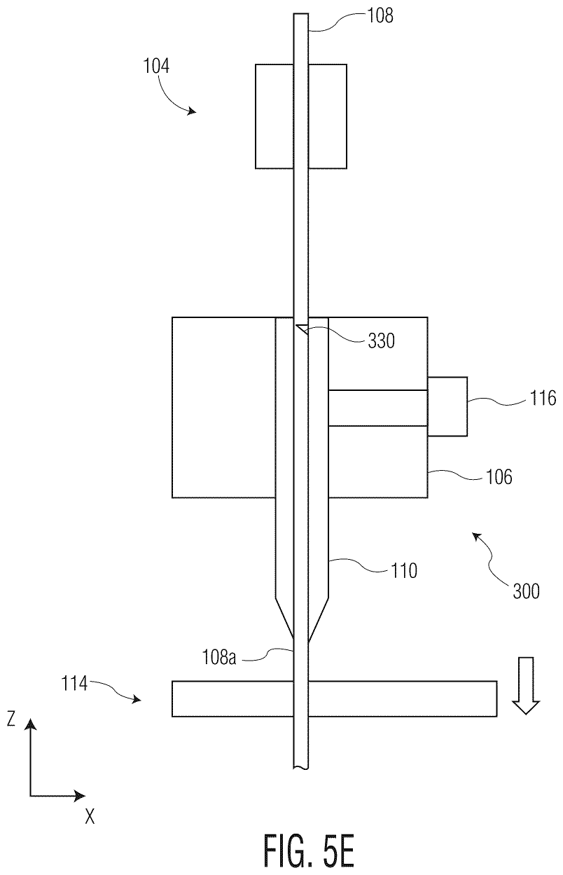

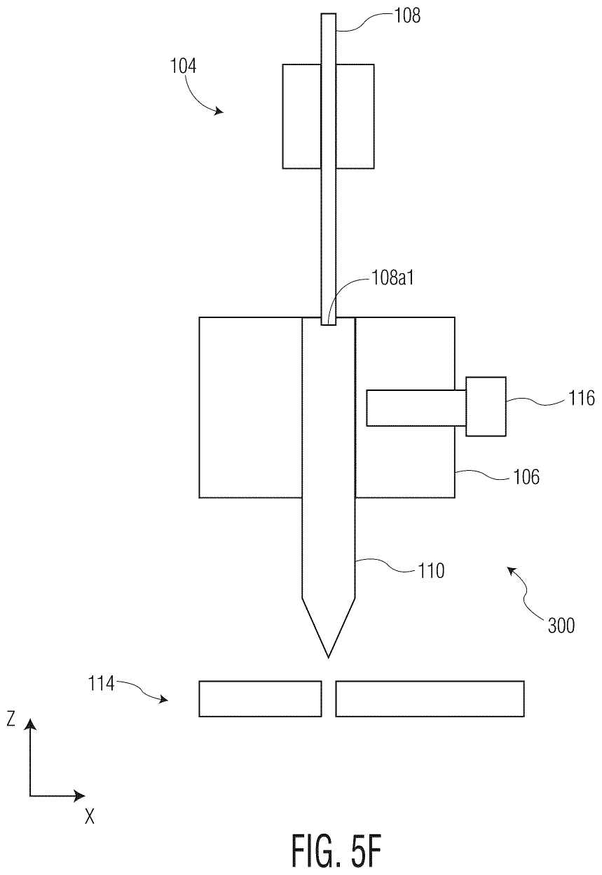

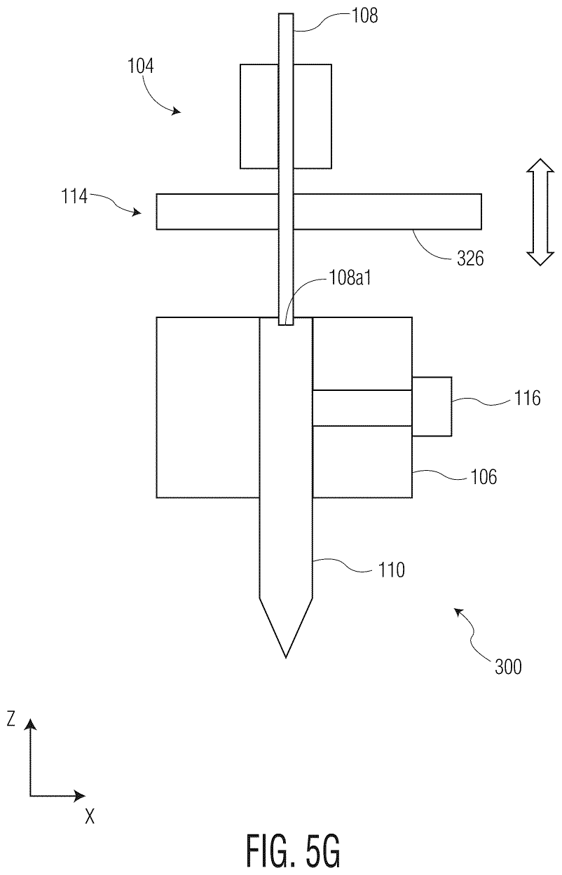

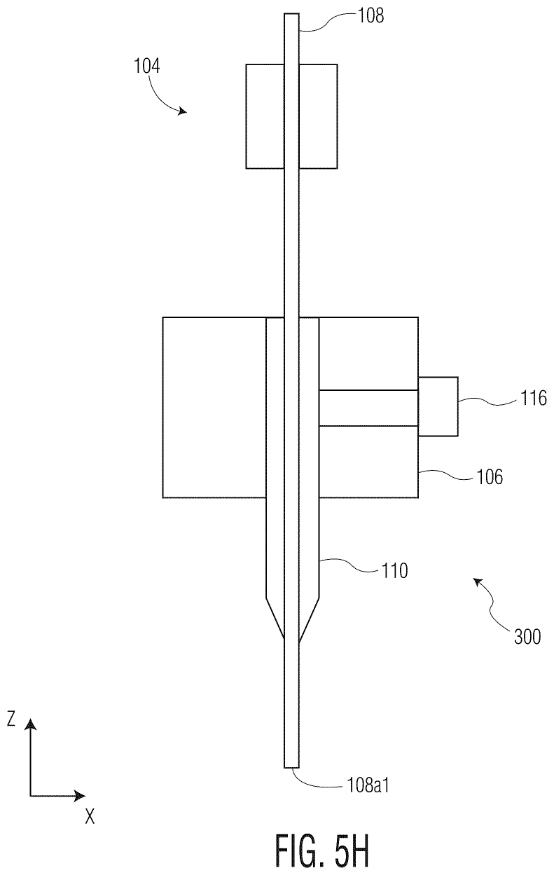

Referring now to FIG. 1D, wire bonding tool replacement system 112a and clamping mechanism 114 are illustrated removing a wire bonding tool 110 from (i.e., along the z-axis) a wire bonding tool source 120. Wire bonding tool source 120 defines a receptacle 120a for waste (e.g., used wire bonding tools 110, a portion of wire after it is removed by the wire replacement system, as in FIGS. 4A-4D and 5A-5H). Clamping mechanism 114 is illustrated clamping wire bonding tool 110 (e.g., a “new” or undamaged wire bonding tool) and beginning to move wire bonding tool 110 away from wire bonding tool source 120 (i.e., along the z-axis).

Clamping mechanism 114 is configured for retrieving wire bonding tool 110 from wire bonding tool source 120, and for carrying wire bonding tool 110 to bond head assembly 102. Such a configuration may include sizing certain clamping portions such that clamping mechanism 114 can retrieve one of a plurality of wire bonding tools 110. Such a configuration may also include mechanically coupling portions of clamping mechanism 114 to a motion system (e.g., of wire bonding tool replacement system 112a) for moving clamping mechanism 114 across a range of motion (e.g., from bond head assembly 102 to wire bonding tool source 120). Such a motion system can be configured to implement computer-readable instructions; such computer-readable instructions may include information related to: the plurality of wire bonding tools 110 (e.g., positional or dimensional information of each of the plurality of wire bonding tools 110) and motion profiles, and/or predetermined events (e.g., a number of bonding operations; time since installation; other information related to automatic replacement of the wire bonding tool upon the occurrence of a predetermined event; etc.).

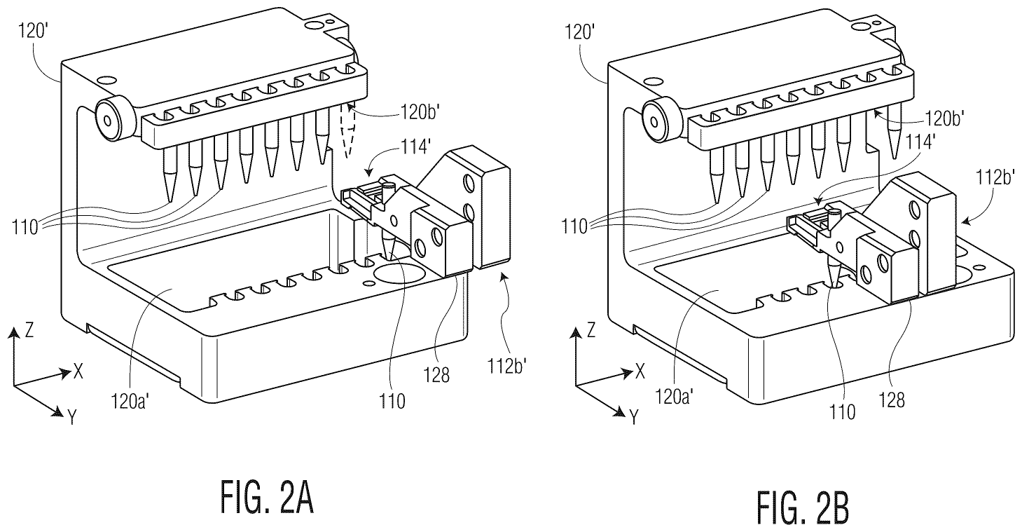

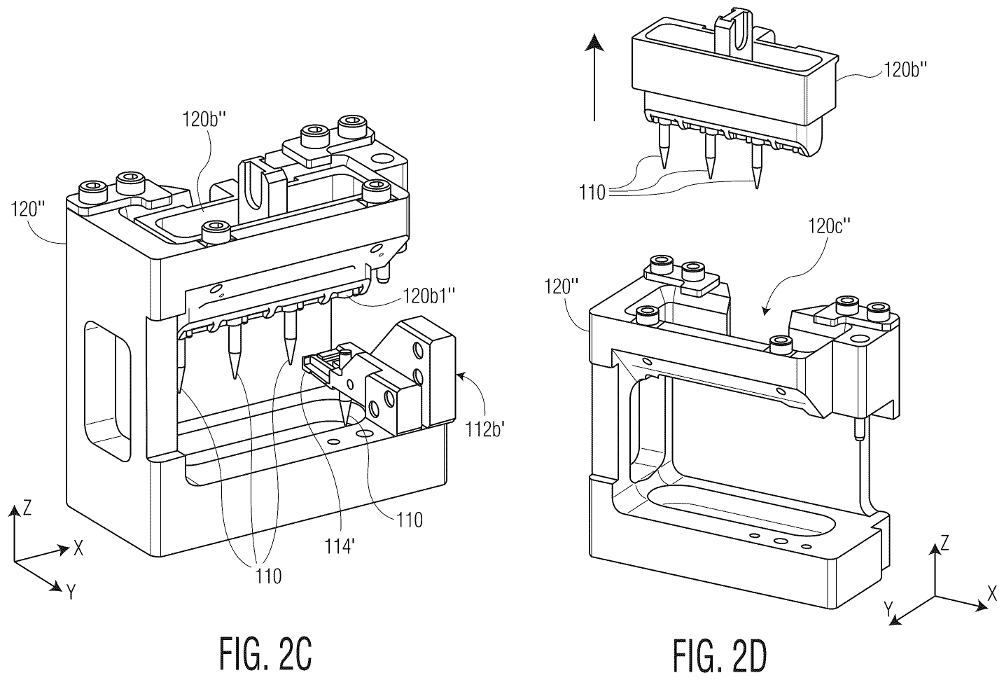

Although FIG. 1D illustrates wire bonding tool source 120 in a particular configuration, the invention is not limited thereto. Other configurations of a wire bonding tool source are contemplated. For example, any number of slots for the plurality of wire bonding tools 110 is contemplated. A wire bonding tool source may be configured to hold wire bonding tools 110 at a top side rather than at the bottom side as illustrated in FIG. 1D. Such a wire bonding tool source is illustrated and described herein (e.g., see FIGS. 2A-2D). Wire bonding tools can be provided individually or as part of a cartridge (e.g., see FIGS. 2C-2D). A wire bonding tool source may be included as part of a wire bonding tool replacement system and/or a wire replacement system (e.g., structurally integrated, electrically integrated) or separate from a wire bonding tool replacement system. A receptacle is not required.

Referring now to FIG. 1E, wire bonding tool replacement system 112a and clamping mechanism 114 are illustrated moving wire bonding tool 110 (i.e., along the z-axis) beneath transducer 106.

Referring now to FIG. 1F, wire bonding tool 110 is disposed within transducer 106. Wrench 118 (e.g., a cap screw wrench) is illustrated rotating about the x-axis to tighten screw 116 (e.g., a cap screw), thereby tightening transducer 106 to grip wire bonding tool 110. After tightening transducer 106 (and/or simultaneously), clamping mechanism 114 may unclamp from wire bonding tool 110 (e.g., moving first clamp portion 114a with respect to second clamp portion 114b).

Although wire bonding tool replacement system 112a/wire replacement system 112b can be included in a single wire bonding system (e.g., a single wire bonding machine), the invention is not so limited. In certain embodiments, wire bonding tool replacement system 112a/wire replacement system 112b can be configured to be removed from wire bonding system 100 and used in connection with another wire bonding system. In certain embodiments, wire bonding tool replacement system 112a/wire replacement system 112b can be moved automatically (e.g., via a robot) between a plurality of wire bonding systems.

Referring now to FIGS. 2A-2D, wire bonding tool sources that may be used in place of wire bonding tool source 120 are illustrated. In particular, FIGS. 2A and 2B illustrate a wire bonding tool source 120′, and FIGS. 2C and 2D illustrate a wire bonding tool source 120″. Wire bonding tool sources 120′ and 120″ are configured to simultaneously (i) provide the plurality of wire bonding tools 110 (e.g., each of the plurality of wire bonding tools 110 may be installed in a slot of wire bonding tool source 120′/120″), and (ii) provide a receptacle (such as a receptacle 120a′ defined by wire bonding tool source 120′, or an empty slot 120b′ or 120b1″) to receive wire bonding tools from a wire bonding system (e.g., to receive used wire bonding tools, etc.).

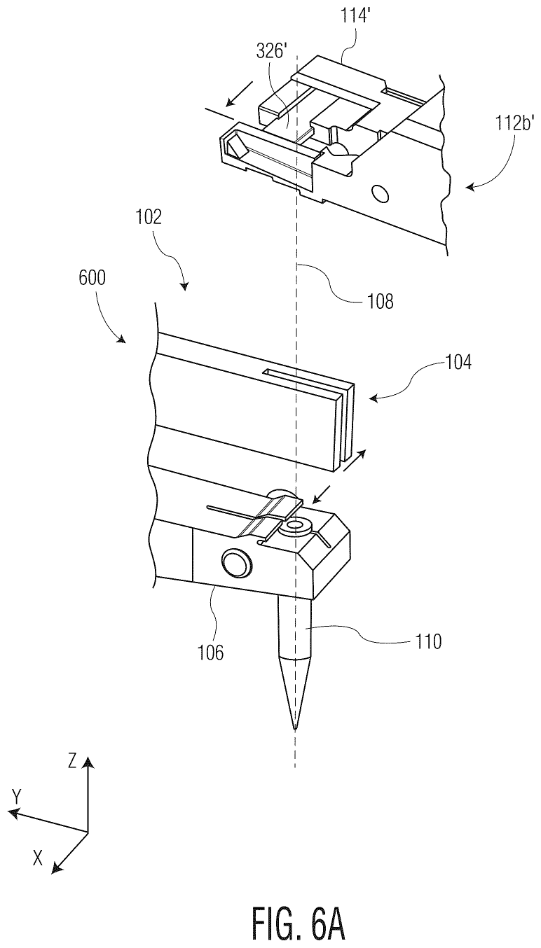

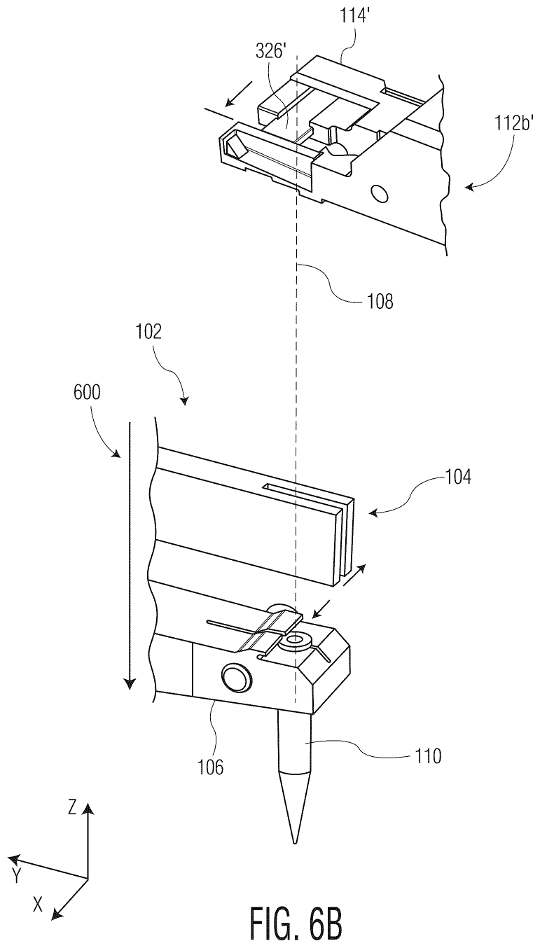

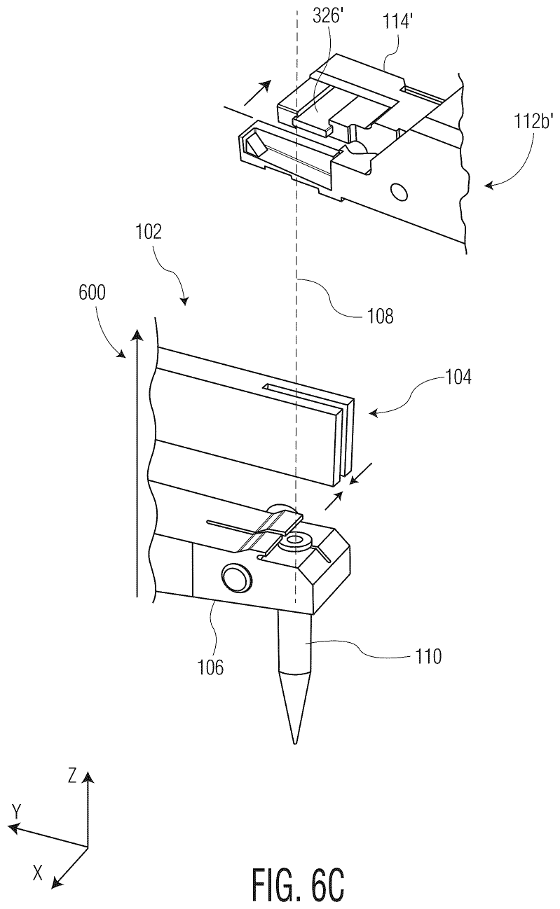

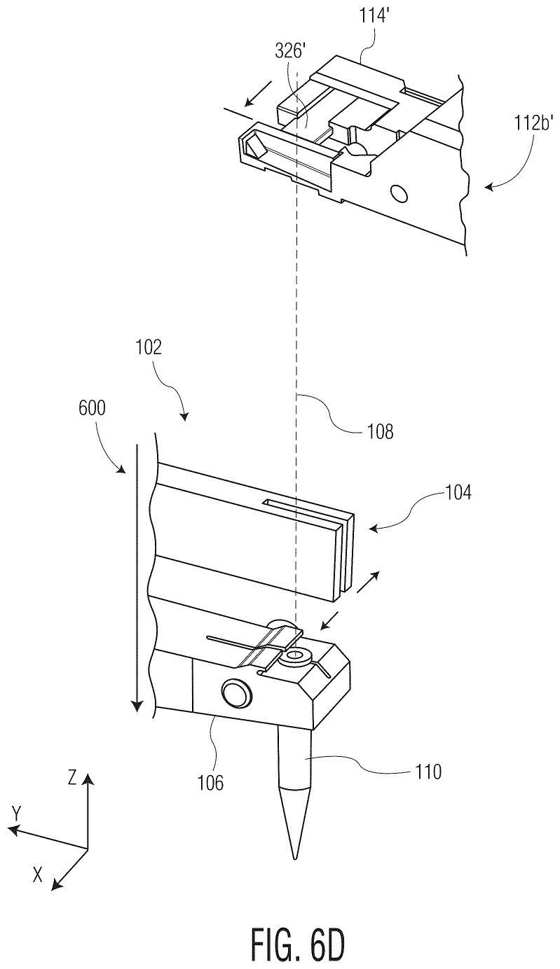

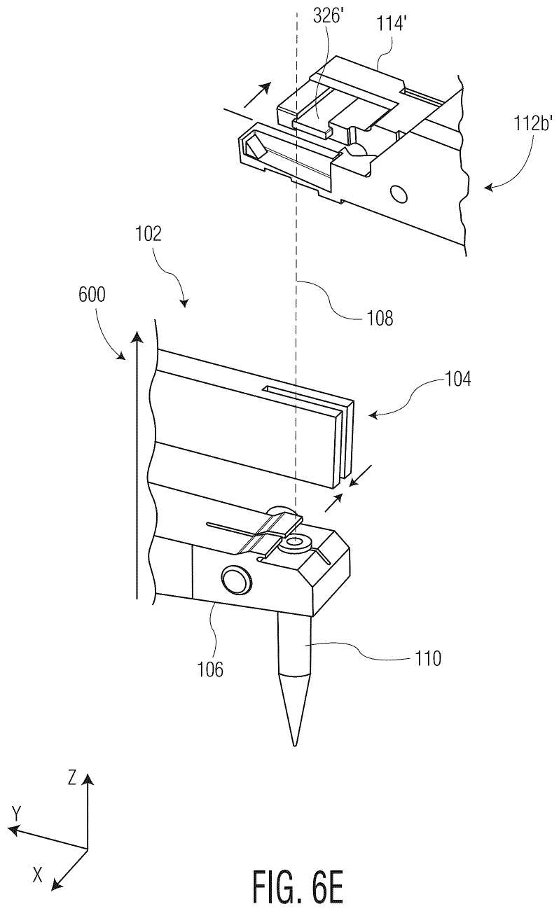

FIG. 2A illustrates wire replacement system 112b′ interacting with wire bonding tool source 120′ (wire replacement system 112b′ will be described in connection with FIGS. 6A-6E) (where wire replacement system 112b′ is configured to replace wire bonding tool 110). Wire replacement system 112b′ is carrying wire bonding tool 110 with clamping mechanism 114′ (e.g., a used wire bonding tool 110 that has been removed from transducer 106, as in FIG. 1C). Wire replacement system 112b′ is aligned with empty slot 120b′ so that wire bonding tool 110 (e.g., a used wire bonding tool) can be installed into empty slot 120b′. By receiving wire bonding tool 110 in this manner, empty slot 120b′ serves as a receptacle (as opposed to using receptacle 120a′) for receiving wire bonding tool 110 (e.g., a used wire bonding tool) to remove waste from a wire bonding system.

While FIG. 2A illustrates the use of empty slot 120b′ to receive wire bonding tool 110, the invention is not so limited. It is contemplated that receptacle 120a′ may be used to receive at least one of (i) wire bonding tools (e.g., used wire bonding tools), and (ii) wire (e.g., wire portion 108a after it has been removed, as in FIGS. 5E-5F, described herein).

In FIG. 2B, wire bonding tool 110 has been inserted into empty slot 120b′, and wire replacement system 112b′ has removed another wire bonding tool 110 from wire bonding tool source 120′, creating a new empty slot 120b′ (e.g., wherein another “used” wire bonding tool 110 can be inserted into new empty slot 120b′). Wire replacement system 112b′ may install wire bonding tool 110 into the transducer of a wire bonding system (e.g., see FIGS. 1E and 1F).

When some or all of the plurality of wire bonding tools 110 have been removed from wire bonding tool source 120′ (and possibly replaced with used wire bonding tools 110), wire bonding tool source 120′ may be removed from wire replacement system 112b′. Alternatively, used wire bonding tools 110 may be removed and/or replaced individually (e.g., manually or via an automated process).

In FIG. 2C, wire bonding tool source 120″ includes a wire bonding tool cartridge 120b″ that contains a plurality of wire bonding tools 110 and an empty slot 120b1″. Wire bonding tool cartridge 120b″ is an example of a mechanism used to hold the plurality of wire bonding tools 110, such that the plurality of wire bonding tools 110 can be loaded into wire bonding tool source 120″ efficiently. FIG. 2C illustrates wire replacement system 112b′ (including clamping portion 114) inserting wire bonding tool 110 into empty slot 120b1″ (e.g., in a similar manner as described in connection with FIGS. 2A and 2B).

In FIG. 2D, wire bonding tool cartridge 120b″ is being removed from wire bonding tool source 120″, revealing a cartridge dock 120c″ defined by wire bonding tool source 120″. Cartridge dock 120c″ is configured to receive another wire bonding tool cartridge 120b″. After removal, wire bonding tool cartridge 120b″ may be disposed of or reloaded with other/new wire bonding tools (e.g., manually or via an automated process). Wire bonding tool cartridge 120b″ may be configured to include a cover to protect the plurality of wire bonding tools 110 from damage during shipping and handling.

Although FIGS. 2A-2D illustrate wire replacement system 112b′ interacting with wire bonding tool sources 120′, 120″, the invention is not limited thereto. That is, any wire bonding tool replacement system or wire replacement system within the scope of the invention (e.g., wire bonding tool replacement system 112a, wire replacement system 112b, etc.) may be utilized to interact with any wire bonding tool source within the scope of the invention (e.g., wire bonding tool sources 120′, 120″).

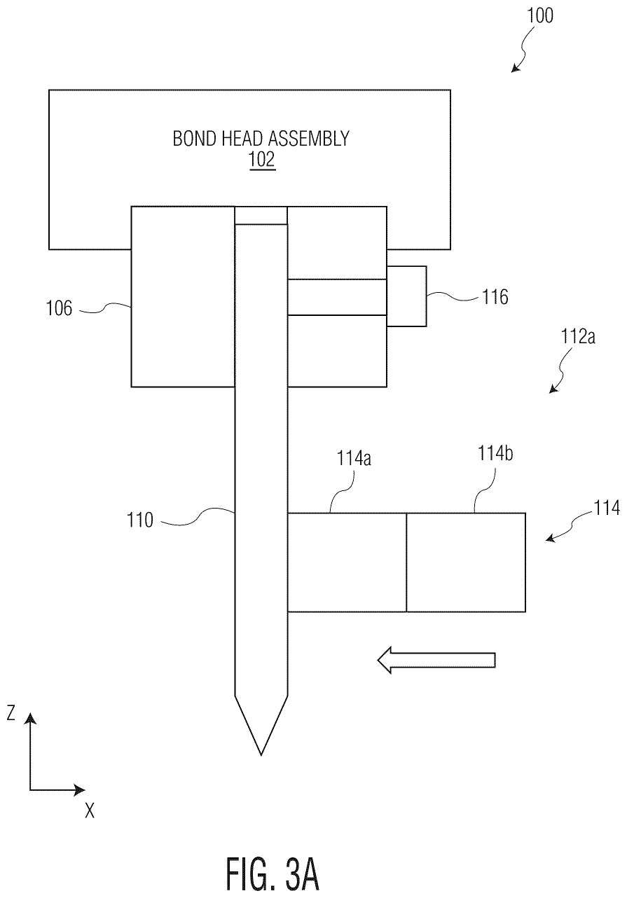

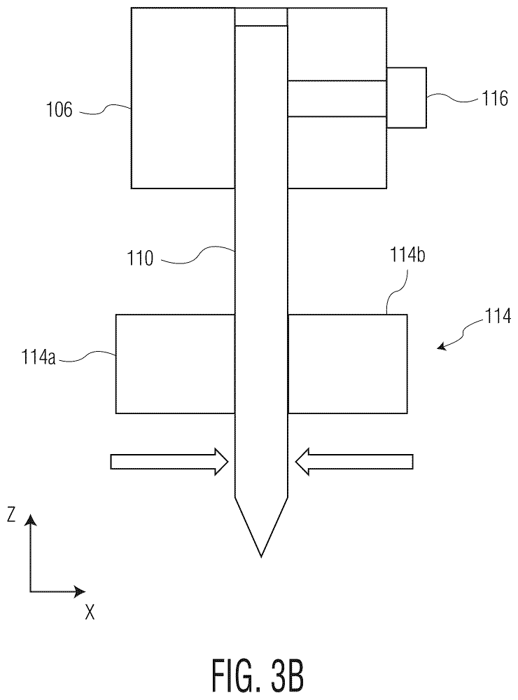

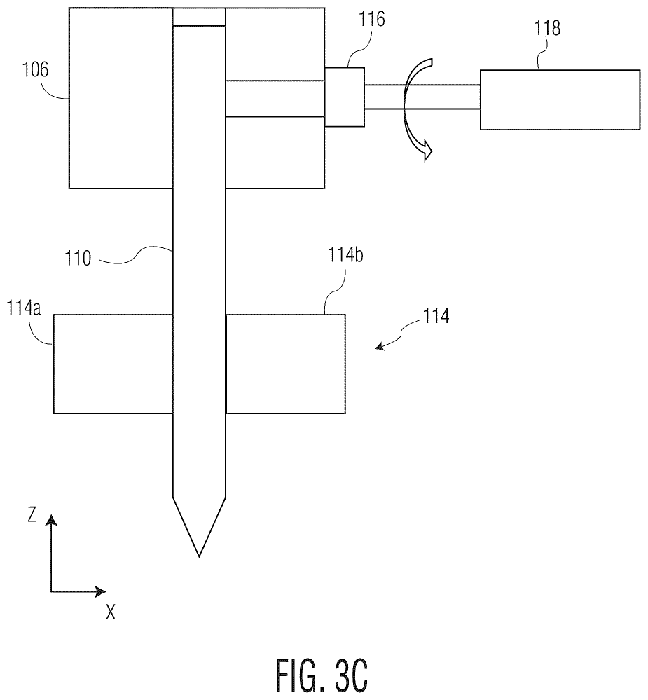

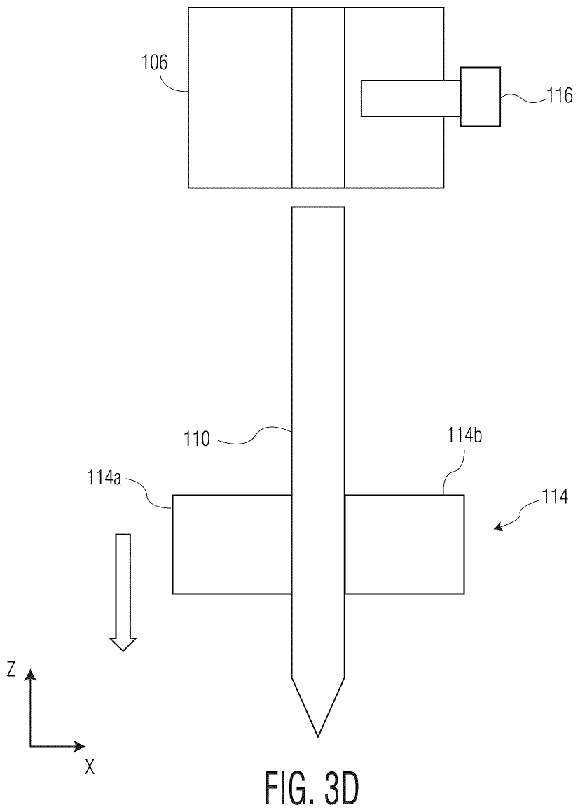

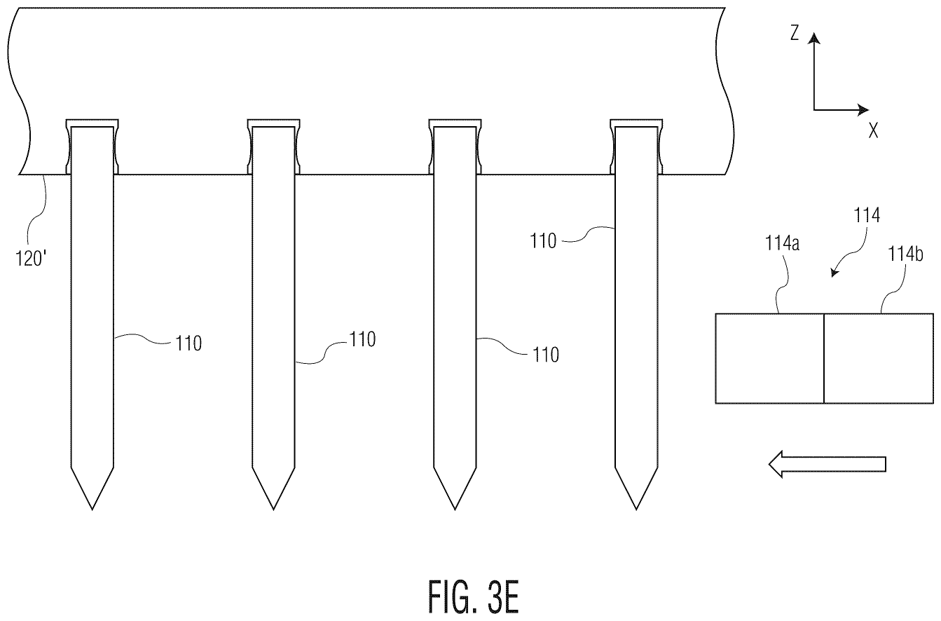

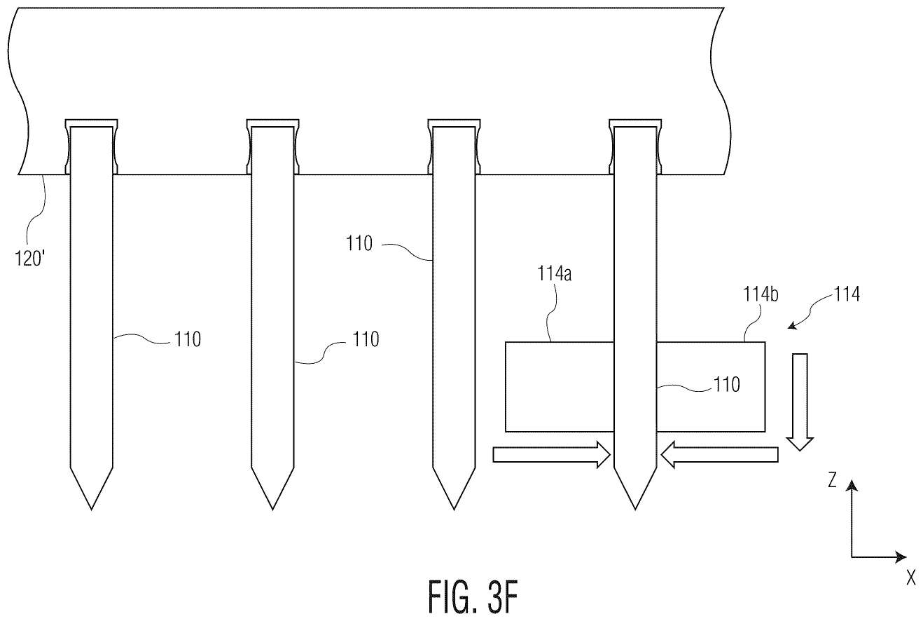

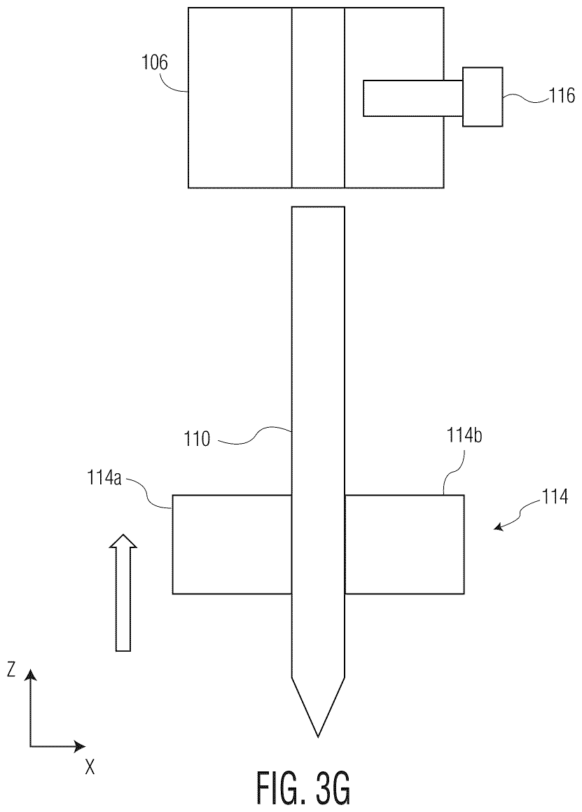

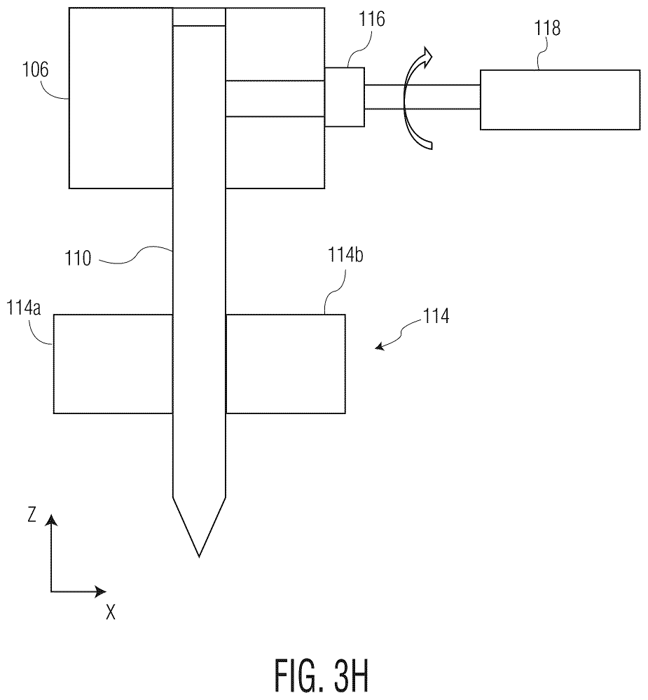

Referring now to FIGS. 3A-3H, various block diagram side views of select portions of wire bonding system 100 are illustrated. Referring specifically to FIG. 3A, wire bonding system 100 is illustrated including bond head assembly 102 (including transducer 106). Wire bonding tool 110 is illustrated being carried by bond head assembly 102 and disposed within transducer 106. Wire bonding system 100 also includes wire bonding tool replacement system 112a (illustrated in part). Wire bonding tool replacement system 112a is configured to replace wire bonding tool 110 with another wire bonding tool (e.g., another wire bonding tool 110). Wire bonding tool replacement system 112a is illustrated including clamping mechanism 114 for clamping and removing wire bonding tool 110 from bond head assembly 102. Clamping mechanism 114 includes first clamp portion 114a (e.g., a moving clamp portion), and second clamp portion 114b (e.g., a fixed clamp portion) adjacent first clamp portion 114a. In FIG. 3B, clamping mechanism 114 is illustrated gripping wire bonding tool 110.

Referring now to FIG. 3C, wrench 118 (e.g., a cap screw wrench) is illustrated rotating about the x-axis to loosen screw 116 (e.g., a cap screw), thereby loosening transducer 106 to release wire bonding tool 110. Prior to loosening transducer 106 (and/or simultaneously), clamping mechanism 114 may clamp wire bonding tool 110 (e.g., moving first clamp portion 114a with respect to second clamp portion 114b).

Referring now to FIG. 3D, clamping mechanism 114 is illustrated moving wire bonding tool 110 away from (i.e., along the z-axis) bond head assembly 102 and transducer 106. Wire bonding tool 110 can be disposed of prior to retrieving another wire bonding tool.

Referring now to FIG. 3E, wire bonding tool source 120′ is illustrated including a plurality of wire bonding tools 110 (i.e., in the block diagram representation in FIGS. 3E-3F, only four wire bonding tools 110, and corresponding slots, are shown). Second clamp portion 114b is illustrated adjacent to wire bonding tool source 120′.

Referring now to FIG. 3F, clamping mechanism 114 is illustrated removing a wire bonding tool 110 from (i.e., along the z-axis) wire bonding tool source 120′.

Referring now to FIG. 3G, clamping mechanism 114 is illustrated moving wire bonding tool 110 (i.e., along the z-axis) beneath transducer 106.

Referring now to FIG. 3H, wire bonding tool 110 is illustrated disposed within transducer 106. Wrench 118 (e.g., a cap screw wrench) is illustrated rotating about the x-axis to tighten screw 116 (e.g., a cap screw), thereby tightening transducer 106 to grip wire bonding tool 110. After tightening transducer 106 (and/or simultaneously), clamping mechanism 114 may unclamp from wire bonding tool 110 (e.g., moving first clamp portion 114a with respect to second clamp portion 114b).

Although wire bonding system 100 (described in connection with FIGS. 1A-1F and 3A-3H) is configured to remove and replace (e.g., automatically) a wire bonding tool, the invention is not so limited. For example, a similar wire bonding system can be used in connection with removing and replacing wire (e.g., automatically). Moveable arm assembly 128 and/or clamping mechanism 114 can be configured for removing wire from wire bonding tool 110, and for replacing wire in connection with replacement of wire bonding tool 110. In one aspect, clamping mechanism can include (i) a gripping portion for gripping wire, (ii) a cutting portion for partially cutting wire, and (iii) a threading portion for threading wire (in addition to a tool clamping portion for clamping the wire bonding tool).

Referring now to FIG. 4A, wire replacement system 112b of a wire bonding system 300 is illustrated (illustrated in part). It should be understood that wire replacement system 112b shares many of the same elements and aspects as wire bonding tool replacement system 112a described elsewhere herein (e.g., FIGS. 1A-1D, FIGS. 3A-3H, etc.) in connection with wire bonding system 100. For example, FIG. 4A illustrates various elements of clamping mechanism 114-including illustrating wire bonding tool 110 being clamped by clamping mechanism 114.

Wire replacement system 112b is configured to (i) remove a portion of a wire engaged with wire bonding tool 110, and (ii) to replace the wire portion (e.g., with the same wire portion, or with another wire portion). Wire replacement system 112b includes clamping mechanism 114 configured to clamp wire.

Clamping mechanism 114 is illustrated including first clamp portion 114a (e.g., a moving clamp portion) and second clamp portion 114b (e.g., a fixed clamp portion) disposed adjacent first clamp portion 114a. Clamping mechanism 114 is illustrated including spring 122 configured to actuate a moving clamp portion (e.g., first clamp portion 114a) with respect to a fixed clamp portion (e.g., second clamp portion 114b). Clamping mechanism 114 is illustrated including gripping portions 114a1/114b1 for gripping wire. Clamping mechanism 114 is illustrated including a cutting portion 324 for cutting wire (e.g., fully cutting wire, half cutting wire, partially cutting wire, creating an incision, etc.). Clamping mechanism 114 is illustrated including a threading portion 326 for threading wire. Clamping mechanism 114 is illustrated including tool clamping portion 114b2 for clamping wire bonding tool 110. In certain embodiments, clamping mechanism 114 may be carried by moveable arm assembly 128.

Moveable arm assembly 128 is configured to move clamping mechanism 114 independent of bond head assembly 102 and/or an X-Y table that carries bond head assembly 102. Thus, clamping mechanism 114 is distinguished from wire clamp 104 in that wire clamp 104 is part of bond head assembly 102, and thus cannot be moved independently from bond head assembly 102. Moveable arm assembly 128 may have its own motion system/positioning system, e.g., wherein the motion system/positioning system is housed within wire bonding tool replacement system 112a/wire replacement system 112b.

Referring now to FIG. 4B, wire bonding system 300 is illustrated. Wire bonding system 300 includes bond head assembly 102 (illustrated in part) configured to carry wire bonding tool 110. Bond head assembly 102 is illustrated including wire clamp 104 and transducer 106. Wire supply 108 is illustrated disposed through both wire clamp 104 and transducer 106. Wire portion 108a of wire supply 108 is illustrated disposed through wire bonding tool 110.

Wire bonding system 300 also includes wire replacement system 112b (illustrated in part) configured to (i) remove a portion of wire engaged with wire bonding tool and (ii) to replace the wire portion (e.g., with the same wire portion or with another wire portion). It should be understood that while wire replacement system 112b may primarily replace wire, the invention is not so limited; in certain embodiments, wire replacement system 112b may be configured to provide (or remove) wire bonding tool 110 to (or from) bond head assembly 102. It should be understood that wire bonding tool 110 may have been provided to transducer 106 (of bond head assembly 102) by wire replacement system 112b.

In FIG. 4B, wire replacement system 112b is illustrated cutting wire supply 108 with cutting portion 324 (e.g., a “half-cut blade”) to partially cut (e.g., “half cutting”) wire supply 108. Clamping mechanism 114 has been positioned (e.g., along the z-axis while in an “open” configuration) and then closed to perform a cutting operation to form a “half-cut” (or partial sever) on wire supply 108. It should be understood that cutting portion 324 may be spring controlled (e.g., using spring 122) and may provide a clamping force which is different from a gripping force or cutting force. Wire clamp 104 may be in a “closed” configuration during this cutting operation.

After cutting wire supply 108, wire clamp 104 may be opened (i.e., in an “opened” configuration) and clamping mechanism 114 of wire replacement system 112b can be moved away from wire clamp 104 (i.e., down or along the z-axis) to feed wire supply 108 through wire bonding tool 110.

In FIG. 4C, a cutting operation and first wire feed operation have been completed. Clamping mechanism 114 of wire replacement system 112b is illustrated having been moved below wire bonding tool 110. Clamping mechanism 114 can grip wire portion 108a with gripping portion 114a1 (and gripping portion 114b1, not illustrated) and feed wire supply 108 in connection with a feeding operation. Such a feeding operation can be repeated for a plurality of cycles (e.g., two cycles, three cycles, etc.). Such a feeding operation includes opening and closing wire clamp 104 in connection with each cycle. At the end of the feeding operation, the partial cut is approximately aligned with the top of wire bonding tool 110. Then, wire clamp 104 is closed and clamping mechanism 114 can pull on wire supply 108 (e.g., along the z-axis) such that wire supply 108 breaks at the partial cut/incision. In certain embodiments, a new wire bonding tool can be provided after breaking wire supply 108 at the partial cut/incision.

In FIG. 4D, wire supply 108 has been broken at the partial cut/incision and clamping mechanism 114 of wire replacement system 112b is illustrated having been moved above transducer 106. Clamping mechanism 114 is illustrated closed around wire supply 108 using threading portion 326 (e.g., a threading blade). Clamping mechanism 114 can move away from wire clamp 104 in connection with a threading process. Such a threading process can be repeated for a plurality of cycles (e.g., two cycles, three cycles, etc.). Such a threading process includes opening and closing wire clamp 104 in connection with each cycle. Such a threading process is repeated until wire portion 108a extends to a desired length (e.g., such that wire portion 108a extends out from wire bonding tool 110, as shown in FIG. 4D). At the end of the threading process, wire clamp 104 is closed.

FIGS. 5A-5H illustrate various cross-sectional block diagrams of portions of wire bonding system 300 and/or wire replacement system 112b, in connection with certain exemplary embodiments of the invention.

In FIG. 5A, clamping mechanism 114 of wire replacement system 112b is illustrated. Clamping mechanism 114 is illustrated including first clamp portion 114a (a moving clamp portion) and second clamp portion 114b (e.g., a fixed clamp portion) disposed adjacent to first clamp portion 114a. First clamp portion 114a is configured to move with respect to second clamp portion 114b in at least one direction. Clamping mechanism 114 is illustrated including a gripping portion 114a1 for gripping wire, a cutting portion 324 for cutting (e.g., half cutting) wire, and a threading portion 326 for threading wire. Clamping mechanism 114 is illustrated including tool clamping portion 114b2 for clamping a tool (e.g., wire bonding tool 110).

Clamping mechanism 114 is illustrated including a spring 122 configured to actuate first clamp portion 114a with respect to second clamp portion 114b. Spring 122 is illustrated including a plurality of springs, including spring 122a (configured to provide a cutting force for cutting portion 324) and spring 122b (configured to provide a gripping force for threading portion 326). Cutting portion 324 and threading portion 326 may be spring controlled with different mechanical forces from each other (e.g., different spring constants).

In FIG. 5B, clamping mechanism 114 is illustrated disposed above transducer 106 prior to a cutting operation. Cutting portion 324 is illustrated adjacent wire supply 108 with clamping mechanism 114 in an “open” position prior to a cutting operation. Wire clamp 104 is illustrated in a “closed” position.

In FIG. 5C, clamping mechanism 114 has been closed in connection with a cutting operation. Clamping mechanism 114 of wire replacement system 112b is illustrated partially cutting wire supply 108 to create an incision 330. Incision 330 defines an end of wire portion 108a to be replaced on wire bonding system 300. Incision 330 has been formed at a location on wire bonding system 300 between wire clamp 104 and wire bonding tool 110. Clamping mechanism 114 may subsequently be moved (e.g., down along the z-axis) in connection with a first feeding operation.

In FIG. 5D, incision 330 has been formed. Clamping mechanism 114 is illustrated having been moved (e.g., down along the z-axis) below wire bonding tool 110 and disposed adjacent wire supply 108. Clamping mechanism 114 has been positioned such that gripping portions 114a1/114b1 are contacting and clamping wire supply 108. Clamping mechanism 114 is illustrated moving farther downward (i.e., along the z-axis) in connection with a feeding operation. Such a feeding operation can be repeated for a plurality of cycles (e.g., two cycles, three cycles, etc.). Such a feeding operation includes opening and closing wire clamp 104 in connection with each cycle.

In FIG. 5E, the feeding operation has been completed, and incision 330 is approximately aligned with the top of wire bonding tool 110. Wire clamp 104 is closed and clamping mechanism 114 can pull on wire portion 108a (e.g., along the z-axis) such that wire supply 108 breaks at incision 330.

In FIG. 5F, wire portion 108a has been removed, thereby forming a new wire end portion 108a1. The removed wire portion 108a may be disposed of in a receptacle (e.g., for waste, such as used wire bonding tools or wire) of wire replacement system 112b (e.g., receptacle 120a of FIG. 1D).

In FIG. 5G, another wire bonding tool 110 has been provided (e.g., using a process described in connection with FIGS. 1A-1F and/or FIGS. 3A-3H). Clamping mechanism 114 has been moved between wire clamp 104 and transducer 106 such that threading portion 326 is positioned to conduct a threading process. The threading process includes pulling an end portion of wire supply 108 through wire bonding tool 110 with clamping mechanism 114. For example, clamping mechanism 114 may grip the end portion of wire supply 108. Then, with wire clamp 104 open, clamping mechanism 114 may be moved such that the end portion of wire supply 108 is moved downward. Then, clamping mechanism 114 may open, wire clamp 104 may close, and clamping mechanism 114 may move upward relative to wire supply 108 and wire clamp 104. The threading process can be repeated for a plurality of cycles (e.g., two cycles, three cycles, etc.). Such a threading process includes opening and closing wire clamp 104 in connection with each cycle. Such a threading process is repeated until wire portion 108a extends to a desired length (e.g., such that wire portion 108a extends out from wire bonding tool 110; such that an adequate wire tail of a desired length is formed, etc.). At the end of the threading process, wire clamp 104 is closed.

In FIG. 5H, the threading process has been concluded and new wire end portion 108a1 is now threaded through wire bonding tool 110.

While FIGS. 4A-4D and 5A-5H illustrate and describe a process of using a half-cut to facilitate the removal of a portion of a wire during a wire bonding tool replacement process, the invention is not so limited. FIGS. 6A-6E illustrate an exemplary process of removing a portion of a wire from a wire bonding tool without cutting the wire on a wire bonding system 600. Each of FIGS. 6A-6E illustrate wire supply 108 disposed through: (i) a clamping mechanism 114′ of wire replacement system 112b′; (ii) bond head assembly 102, including wire clamp 104 and transducer 106; and (iii) wire bonding tool 110 (before wire supply 108 is removed from wire bonding tool 110).

In FIG. 6A, wire replacement system 112b′ is positioned above bond head assembly 102. Clamping mechanism 114′ of wire replacement system 112b′ is engaged against wire supply 108, preventing wire supply 108 from moving relative to clamping mechanism 114′ (e.g., a moving/actuating clamp portion is pressing wire supply 108 against a fixed clamp portion). Wire clamp 104 is in an open position, allowing wire supply 108 to pass through freely.

In FIG. 6B, bond head assembly 102, including wire clamp 104, transducer 106, and wire bonding tool 110, moves downward (i.e., away from clamping mechanism 114′). Since wire clamp 104 is open, bond head assembly 102 and transducer 106 pass over wire supply 108, allowing an end of wire supply 108 to move upward relative to wire bonding tool 110.

In FIG. 6C, clamping mechanism 114′ is open, allowing wire supply 108 to move through clamping mechanism 114′. Wire clamp 104 is closed, preventing wire supply 108 from moving relative to bond head assembly 102. Bond head assembly 102 is moved upward toward clamping mechanism 114′. Since wire clamp 104 is closed, wire supply 108 moves upward with bond head assembly 102 and through clamping mechanism 114′.

In FIG. 6D, clamping mechanism 114′ is closed again, and wire clamp 104 is opened. Bond head assembly 102 is moved downward, allowing wire supply 108 to pass through wire bonding tool 110 until wire supply 108 is removed (e.g., fully removed) from wire bonding tool 110.

In FIG. 6E, wire supply 108 is removed from wire bonding tool 110 such that wire bonding tool 110 may be removed and replaced as described herein (e.g., see FIGS. 1A-1F, FIGS. 2A-2B, and FIGS. 3A-3H). Further, wire supply 108 can be rethreaded/replaced through wire bonding tool 110 (e.g., see FIGS. 4D and 5G, described herein) after the process described in connection with FIGS. 6A-6D.

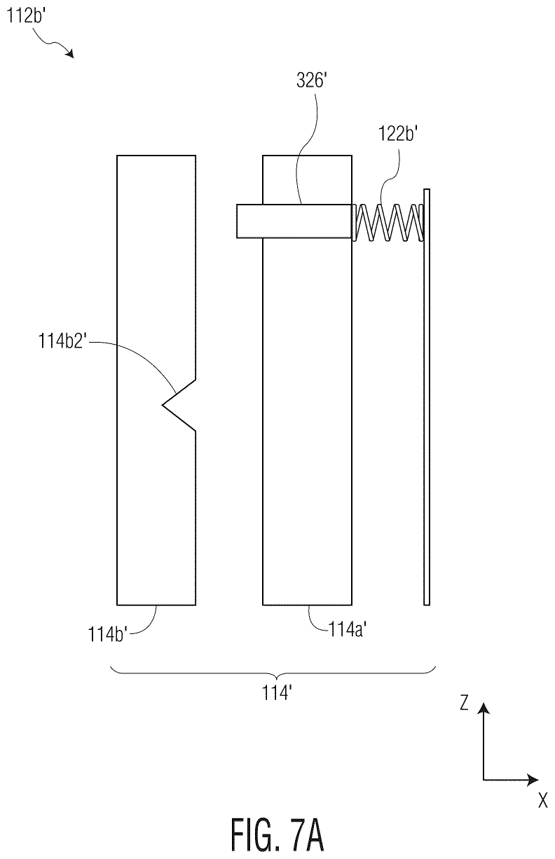

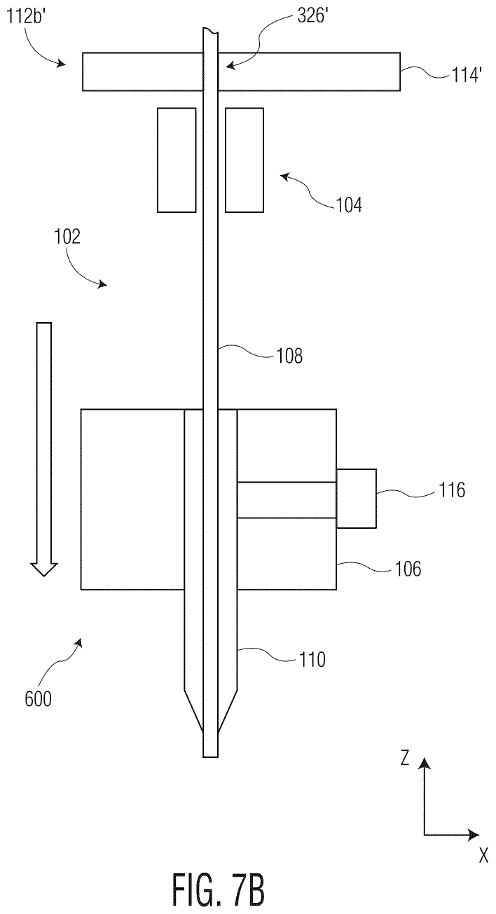

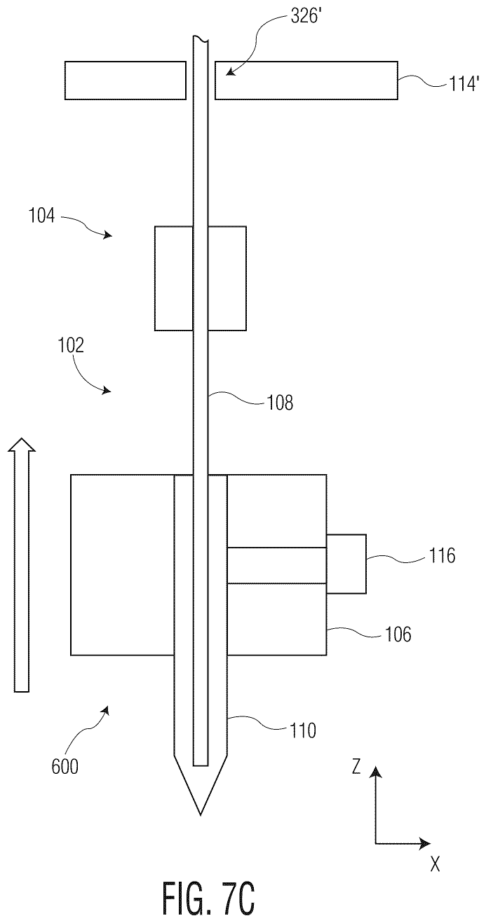

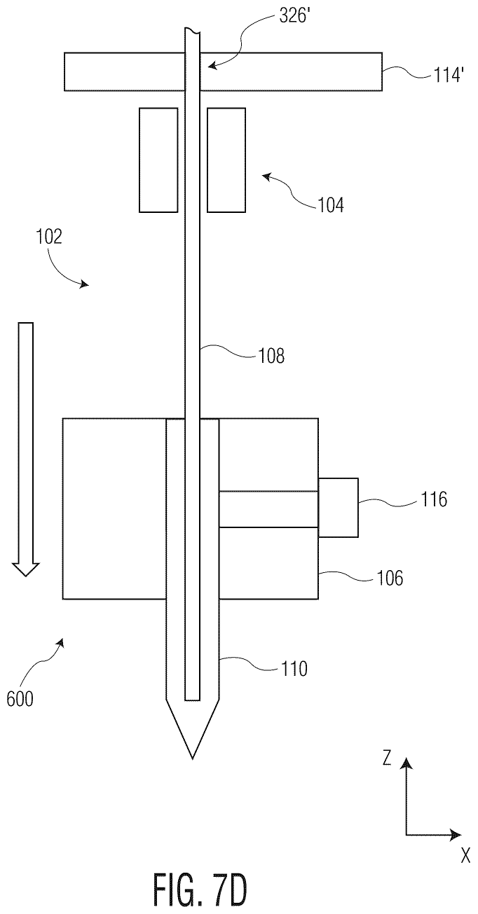

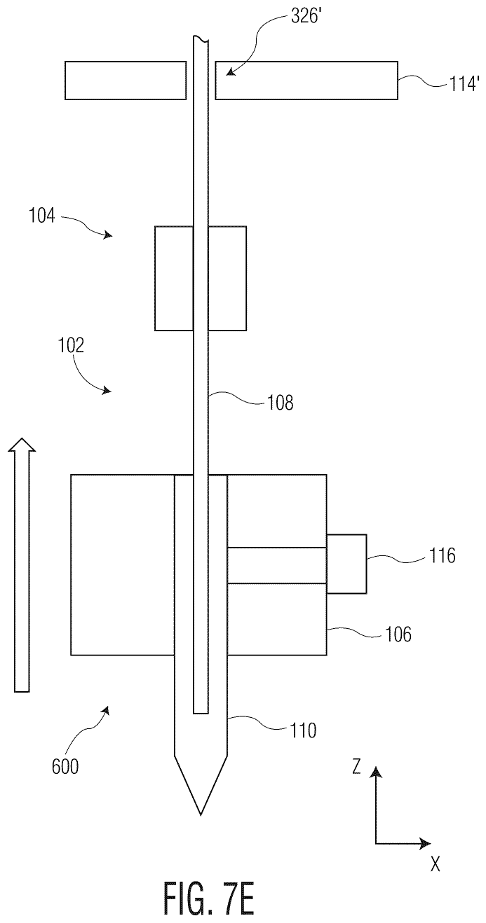

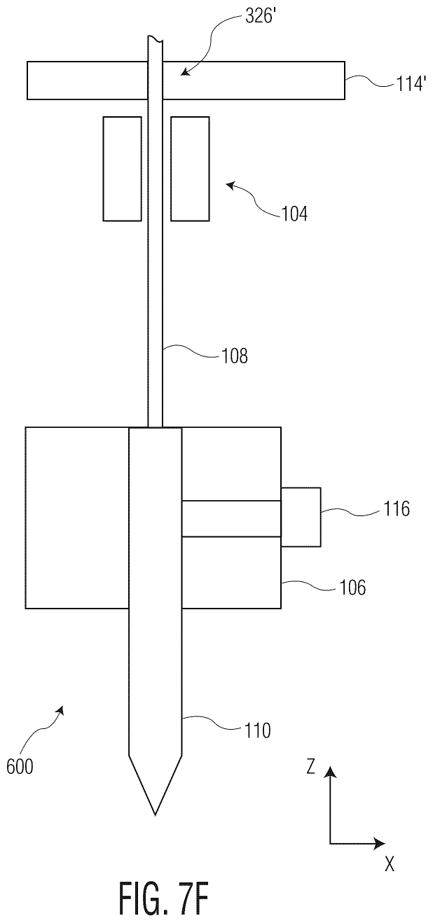

FIGS. 7A-7F illustrate various cross-sectional block diagrams of portions of wire bonding system 600 and/or wire replacement system 112b′, in connection with certain exemplary embodiments of the invention. FIGS. 7A-7F illustrate a similar process as illustrated in FIGS. 6A-6E.

FIG. 7A illustrates wire replacement system 112b′. Wire replacement 112b′ includes clamping mechanism 114′, which includes a first clamp portion 114a′ (a moving clamp portion) and a second clamp portion 114b′ (a fixed clamp portion). First clamp portion 114a′ includes a threading portion 326′. Threading portion 326′ is actuated by a spring 122b′ (e.g., a leaf spring). Second clamp portion 114b′ includes a tool clamping portion 114b2′ for gripping wire bonding tool 110.

In FIG. 7B, wire supply 108 is illustrated as being engaged by threading portion 326′ of clamping mechanism 114′ at a position above wire clamp 104. Wire clamp 104 is open. Thus, wire supply 108 cannot move relative to clamping mechanism 114′, but bond head assembly 102 (including wire clamp 104, transducer 106, and wire bonding tool 110) can move relative to wire supply 108. FIG. 7B illustrates bond head assembly 102 as it is beginning downward motion. Such a downward motion will result in wire supply 108 moving upward relative to bond head assembly 102.

In FIG. 7C, bond head assembly 102 has moved down relative to wire supply 108 (i.e., wire supply 108 is no longer completely threaded through wire bonding tool 110, as in FIG. 7B). Clamping mechanism 114′ is now open, and wire clamp 104 is now closed. Thus, wire supply 108 can move relative to clamping mechanism 114′, and motion of bond head assembly 102 will be transferred to wire supply 108. FIG. 7C illustrates bond head assembly 102 as it is beginning upward motion. Such an upward motion will result in bond head assembly 102 and wire supply 108 moving upward relative to clamping mechanism 114′. Such an upward motion of the wire may be facilitated by an air guide of wire bonding system 600 (not illustrated).

FIG. 7D illustrates bond head assembly 102 having been moved upward. Clamping mechanism 114′ is again closed, and wire clamp 104 is again open. Bond head assembly 102 is beginning a downward motion, such that bond head assembly 102 will move downward relative to wire supply 108 and clamping mechanism 114′. FIG. 7E illustrates bond head assembly 102 having moved downward, with wire supply 108 have been further removed from wire bonding tool 110.

The process illustrated in FIGS. 7B-7E may be repeated several times until wire supply 108 is completely removed from wire bonding tool 110. Such a position is illustrated in FIG. 7F. After wire supply 108 is removed from wire bonding tool 110, wire bonding tool 110 may be replaced with another wire bonding tool 110 (e.g., as illustrated in FIGS. 1A-1F, 2A-2B, and 3A-3H), and wire replacement system 112b′ may replace wire supply 108 by threading it into wire bonding tool 110 (e.g., as illustrated in FIGS. 4D and 5G-5H).

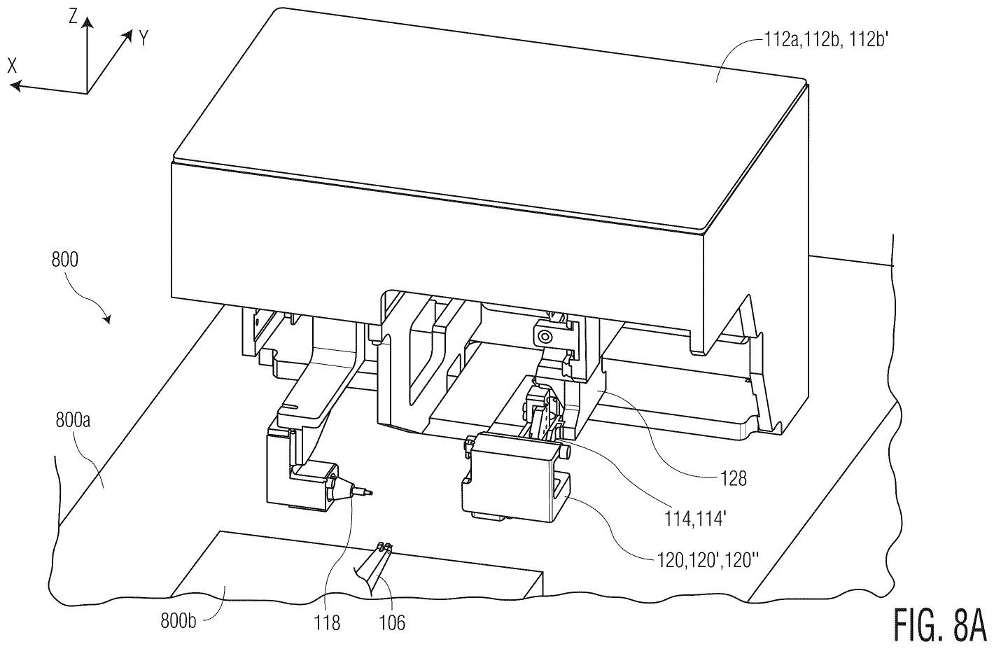

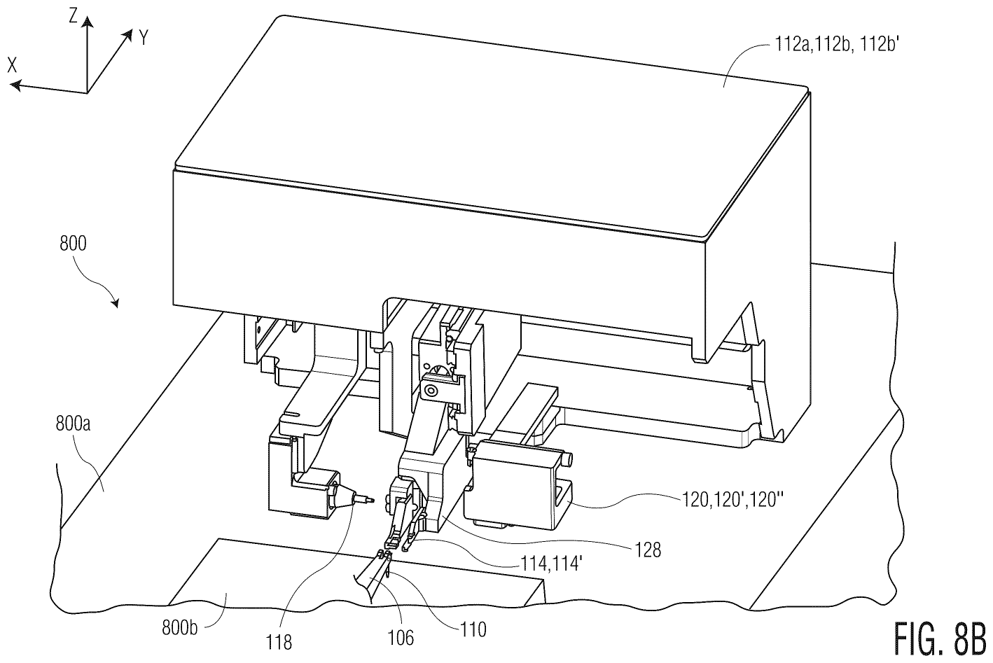

Referring now to FIGS. 8A and 8B, a wire bonding system 800 is illustrated. As illustrated, wire bonding system 800 may include any of wire bonding tool replacement system 112a, wire replacement system 112b, or wire replacement system 112b′. It should be understood that wire bonding tool replacement system 112a shares many of the same elements and aspects as a wire replacement system 112b and 112b′ described elsewhere herein (e.g., FIGS. 4A-4D, FIGS. 5A-5H, etc.).

In FIGS. 8A and 8B, wire bonding tool replacement system 112a (or wire replacement system 112b, 112b′) is retrieving wire bonding tool 110 from wire bonding tool source 120, 120′, 120″ and installing wire bonding tool 110 into transducer 106. A support structure 800b is configured to support a workpiece during a wire bonding operation. Support structure 800b and wire bonding tool replacement system 112a (or wire replacement system 112b, 112b′) are supported by a machine base 800a. Wire bonding tool replacement system 112a (or wire replacement system 112b, 112b′) is illustrated as including (i) clamping mechanism 114/114′ carried by moveable arm assembly 128, (ii) wrench 118, and (iii) wire bonding tool source 120, 120′, 120″.

In FIG. 8A, moveable arm assembly 128 is illustrated at wire bonding tool source 120, 120′, 120″. In such a position, clamping mechanism 114/114′ may be picking a new wire bonding tool 110 (e.g., see FIGS. 1D, 2A, 2C, 3E, and 3F). In FIG. 8B, moveable arm assembly 128 has moved clamping mechanism 114/114′ toward wire bonding tool 110 (e.g., to install wire bonding tool 110, as in FIGS. 1A-1F and 3A-3H, and/or to replace wire, as in FIGS. 4A-4D, 5A-5H, and 6A-6E). In FIG. 8B, wire bonding tool 110 has been installed into transducer 106 (e.g., see FIGS. 1E-1F).

It is contemplated that wire bonding tool replacement system 112a and/or wire replacement system 112b/112b′ may be removeable from machine base 800a. For example, each of machine base 800a and wire bonding tool replacement system 112a may include, for example, (i) an electrical connector for power and/or data communication, and/or (ii) guide pins/locator holes for alignment.

In many operations performed by wire bonding tool replacement system 112a and/or wire replacement system 112b, 112b′, high precision is required to prevent damage or errors (e.g., failing to grip the wire bonding tool, improperly threading the wire, misplacing another wire bonding tool, etc.). As such, it is contemplated that wire bonding tool replacement system 112a and/or wire replacement system 112b/112b′ would include a positioning system to control the position of the clamping mechanism, the moveable arm assembly, and/or the wrench. Exemplary positioning systems may communicate with the wire bonding system. The wire bonding tool replacement system may be configured to provide feedback control in connection with the positioning system. The positioning system may be configured to utilize open/short circuit detection, servo controller feedback, and/or a vision system for positioning.

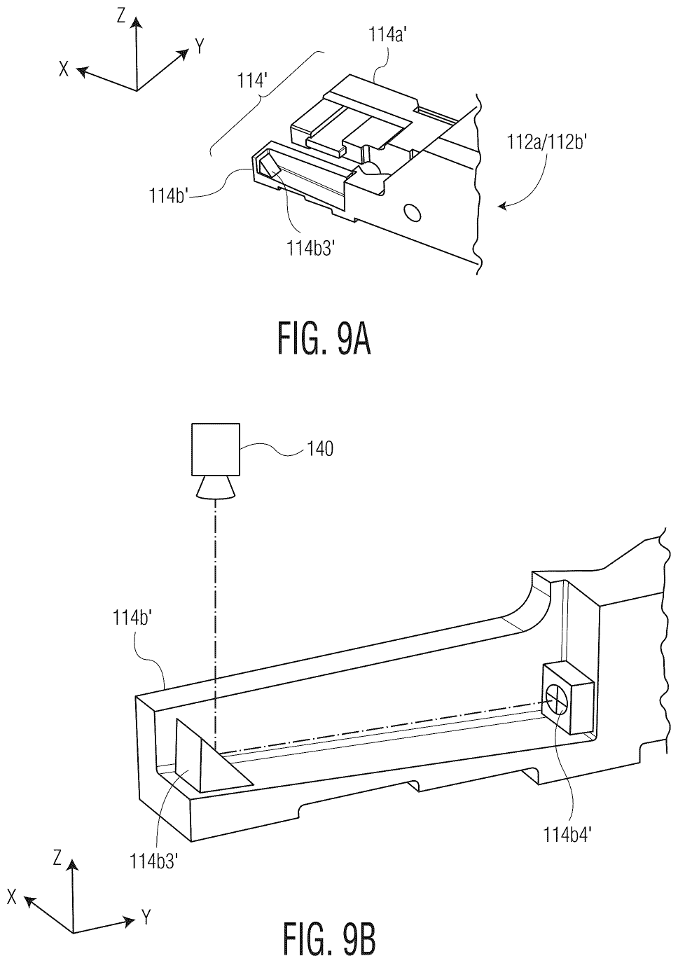

It is contemplated that a vision system of a wire bonding system may be used to determine the precise position of clamping mechanism 114/114′ (and/or the moveable arm assembly, and/or the wrench) of wire bonding tool replacement system 112a and/or wire replacement system 112b/112b′. Such a use of a vision system is illustrated and described with reference to FIGS. 9A and 9B and may be utilized with any wire bonding tool replacement system or wire replacement system within the scope of the invention (e.g., wire bonding tool replacement system 112a, wire replacement system 112b/112b′, etc.).

FIG. 9A illustrates certain common features of a wire bonding tool replacement system 112a and wire replacement system 112b′, including clamping mechanism 114′, first clamp portion 114a′ (e.g., a moving clamp portion), and second clamp portion 114b′ (e.g., a fixed clamp portion). FIG. 9A is provided for reference in relation to FIG. 9B. FIGS. 9A and FIG. 9B illustrate a prism 114b3′, described in greater detail with reference to FIG. 9B.

FIG. 9B illustrates additional detail of second clamp portion 114b′. An eye point 114b4′ is disposed on second clamp portion 114b′ and is oriented toward the wire bonding system (i.e., pointing toward the negative Y direction, as illustrated). Eye point 114b4′ provides a reference feature for determining the location of clamping mechanism 114′. Eye point 114b4′ is illustrated as having a particular image registration feature, but any image registration feature (e.g., a mark or other feature) may be used. Second clamp portion 114b′ includes prism 114b3′. Prism 114b3′ is configured to reflect an image of eye point 114b4′ toward a vision system 140 of a wire bonding system. Prism 114b3′ is a reflective optical element configured to reflect an image of eye point 114b4′ at an angle of approximately 90° (e.g., within a range of 70°-110°). Vision system 140 includes a computer (or other processing means, not illustrated) configured to determine a location of eye point 114b4′ (and thus, clamping mechanism 114′) based on an image collected by vision system 140. Since eye point 114b4′ is rigidly attached to clamping mechanism 114′, the precise location of clamping mechanism 114′ may be determined using images provided by vision system 140. Such position information may be used to determine the movements of clamping mechanism 114′ during a wire bonding tool replacement process (e.g., as illustrated and described with respect to FIGS. 1A-1F and 3A-3H) and/or a wire replacement process (e.g., as illustrated and described with respect to FIGS. 4A-4D, 5A-5H, and 6A-6E).

FIGS. 9A-9B illustrate imaging of an eye point 114b4′ (or other image registration feature) by providing a prism 114b3′ in the optical path. For example, such a prism may be included to extend the working distance of the imaging path to provide a clear image of the eye point. However, it should be understood that a prism (or other reflective optical element) is not required. For example, a more direct imaging path may be utilized, without a prism or reflective optical element. In a specific example, a refracting optical element (e.g., glass, plastic, etc.) may be provided in the imaging path to reduce the working distance of the imaging path to provide a clear image of the eye point (or other image registration feature). Such a refracting optical element may be provided at (or adjacent) the eye point (or other image registration feature). Of course, other configurations are contemplated.

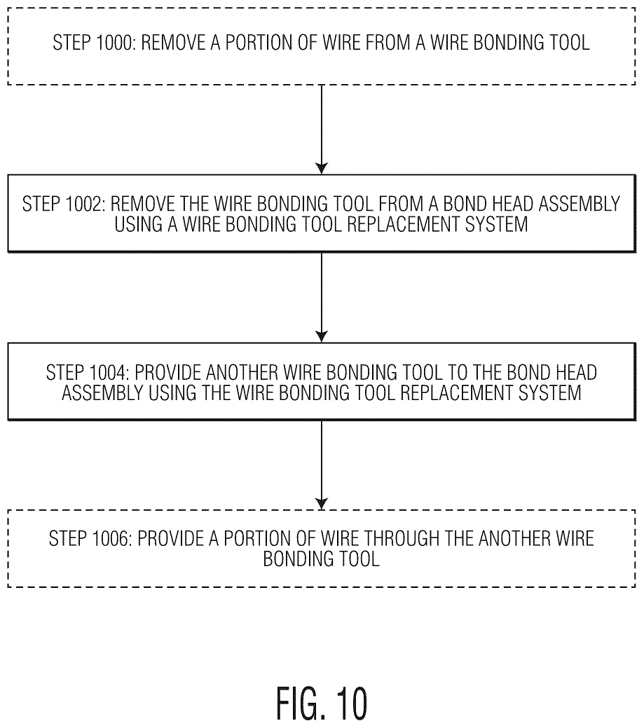

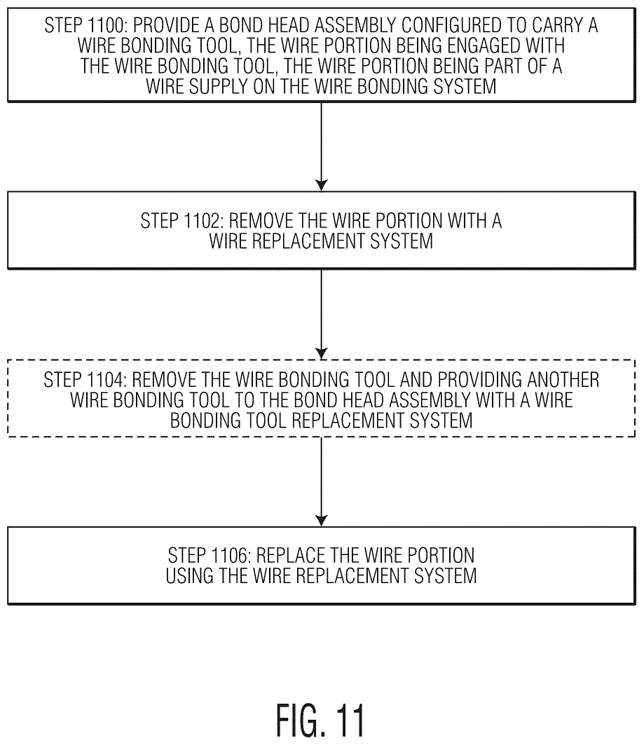

FIGS. 10 and 11 are flow diagrams illustrating exemplary embodiments and/or aspects of the invention. As is understood by those skilled in the art, certain steps included in the flow diagram may be omitted; certain additional steps may be added; and the order of the steps may be altered from the order illustrated-all within the scope of the invention.

Referring now to FIG. 10, a method of replacing a wire bonding tool using a wire bonding tool replacement system on a wire bonding system is illustrated. At optional Step 1000, a portion of wire is removed from a wire bonding tool (e.g., see wire removal process of wire portion 108a from wire bonding tool 110 illustrated in FIGS. 5B-5F and in FIGS. 7A-7F). At Step 1002, the wire bonding tool is removed from a bond head assembly using a wire bonding tool replacement system (e.g., see wire bonding tool removal process illustrated in FIGS. 1A-1D and 3A-3D). At Step 1004, another wire bonding tool is provided to the bond head assembly using the wire bonding tool replacement system (e.g., see FIGS. 3E-3H). At optional Step 1006, a portion of wire is provided through the wire bonding tool (e.g., see FIGS. 5F-5H and FIG. 6E).

Referring now to FIG. 11, a method of replacing a wire portion on a wire bonding system is illustrated. At Step 1100, a bond head assembly configured to carry a wire bonding tool is provided (e.g., see bond head assembly 102 of FIG. 4B). The wire portion is engaged with the wire bonding tool. The wire portion is part of a wire supply on the wire bonding system. At Step 1102, the wire portion is removed with a wire replacement system (e.g., see wire removal process of wire portion 108a from wire bonding tool 110 illustrated in FIGS. 5B-5F and wire removal process of 7A-7F). At optional Step 1104, the wire bonding tool is removed and another wire bonding tool is provided to the bond head assembly with a wire bonding tool replacement system (e.g., see FIGS. 1A-1F). At Step 1106, the wire portion is replaced (e.g., with the removed wire portion, or with another wire portion) using the wire replacement system (e.g., see FIGS. 5F-5H and FIG. 6E).

Although aspects of the invention is illustrated and described herein with reference to creating a partial cut in the wire supply, the invention is not limited thereto. It is contemplated that a cutting portion/clamping portion of a wire bonding tool replacement system or a wire replacement system could be used to fully cut a wire during a wire replacement process.

Although the invention is illustrated and described herein with reference to specific embodiments, the invention is not intended to be limited to the details shown. Rather, various modifications may be made in the details within the scope and range of equivalents of the claims and without departing from the invention.

1. A wire bonding system comprising:
a bond head assembly configured to carry a wire bonding tool; and
a wire bonding tool replacement system for replacement of the wire bonding tool with another wire bonding tool.

2. The wire bonding system of claim 1 wherein the wire bonding tool replacement system includes a clamping mechanism for clamping the wire bonding tool to remove the wire bonding tool from the bond head assembly.

3. The wire bonding system of claim 2 wherein the clamping mechanism includes (i) a threading portion for threading wire and (ii) a tool clamping portion for clamping the wire bonding tool.

4. (canceled)

5. The wire bonding system of claim 2 wherein the clamping mechanism is configured for retrieving the another wire bonding tool from a wire bonding tool source, and for carrying the another wire bonding tool to the bond head assembly.

6. (canceled)

7. (canceled)

8. (canceled)

9. The wire bonding system of claim 2 wherein the clamping mechanism is carried by a moveable arm assembly.

10. The wire bonding system of claim 9 wherein the moveable arm assembly is further configured for removing a wire from the wire bonding tool, and for replacing the wire in connection with replacement of the wire bonding tool.

11. The wire bonding system of claim 1 wherein the wire bonding tool replacement system is configured to be removed from the wire bonding system.

12. (canceled)

13. (canceled)

14. The wire bonding system of claim 1 wherein the wire bonding tool replacement system includes a clamping mechanism for clamping the wire bonding tool to remove the wire bonding tool from the bond head assembly, wherein the clamping mechanism includes an image registration feature, the image registration feature providing a reference for determining a position of the clamping mechanism.

15. The wire bonding system of claim 14 further comprising a vision system configured to determine the position of the clamping mechanism by collecting an image of the image registration feature.

16. (canceled)

17. (canceled)

18. A method of replacing a wire bonding tool using a wire bonding tool replacement system on a wire bonding system, the method comprising the steps of:
removing the wire bonding tool from a bond head assembly using the wire bonding tool replacement system; and
providing another wire bonding tool to the bond head assembly using the wire bonding tool replacement system.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. The method of claim 18 further comprising a step of removing a portion of wire from the wire bonding tool.

31. The method of claim 18 further comprising a step of providing a portion of wire through the another wire bonding tool.

32. A wire bonding tool replacement system for replacing a wire bonding tool on a wire bonding system, the wire bonding tool replacement system comprising:
a clamping mechanism for clamping the wire bonding tool to remove the wire bonding tool from a bond head assembly of the wire bonding system.

33. The wire bonding tool replacement system of claim 32 wherein the clamping mechanism includes (i) a threading portion for threading wire, and (ii) a tool clamping portion for clamping the wire bonding tool.

34. (canceled)

35. The wire bonding tool replacement system of claim 32 wherein the clamping mechanism is configured for retrieving another wire bonding tool from a wire bonding tool source, and for carrying the another wire bonding tool to the bond head assembly.

36. The wire bonding tool replacement system of claim 35 wherein the wire bonding tool source is configured to provide a plurality of wire bonding tools.

37. (canceled)

38. (canceled)

39. The wire bonding tool replacement system of claim 32 wherein the clamping mechanism is carried by a movable arm assembly.

40. The wire bonding tool replacement system of claim 39 wherein the moveable arm assembly is further configured for removing a wire from the wire bonding tool, and for replacing the wire in connection with replacement of the wire bonding tool.

41. The wire bonding tool replacement system of claim 32 wherein the wire bonding tool replacement system is configured for installation in connection with another wire bonding system.

42. (canceled)

43. (canceled)

44. The wire bonding tool replacement system of claim 32 further comprising an image registration feature providing a reference for determining a position of the clamping mechanism.
